(19) United States
(12) Patent Application Publication
(10) Pub. No.: US 2026/0201164 A1
(43) Pub. Date: Jul. 16, 2026

(54) RESIN COMPOSITION AND ARTICLE MANUFACTURED USING THE SAME

(71) Applicant: Elite Material Co., Ltd., Taoyuan City (TW)

(72) Inventors: Shu-Hao CHANG, Taoyuan City (TW); Yueh-Fu LIN, Taoyuan City (TW)

(21) Appl. No.: 19/196,799

(22) Filed: May 2, 2025

(30) Foreign Application Priority Data
Jan. 10, 2025 (TW) 114101072

(51) Int. Cl. C08L 71/12; C08F 212/36; C08J 5/24; C08K 3/36; C08K 5/01; C08K 5/14; C08K 7/18

(52) U.S. Cl. CPC C08L 71/126; C08F 212/36; C08J 5/244; C08K 3/36; C08K 5/01; C08K 5/14; C08K 7/18; C08J 2325/08; C08J 2371/12; C08L 2203/20; C08L 2205/035

(57) ABSTRACT

A resin composition includes: 70 parts by weight of a vinyl-containing resin; 3 parts by weight to 45 parts by weight of a polymer A; and 5 parts by weight to 55 parts by weight of a divinylbenzene-styrene-ethylene terpolymer, wherein the vinyl-containing resin includes a vinyl-containing polyphenylene ether resin, a maleimide resin, a vinyl-containing polyolefin or a combination thereof, and the polymer A includes a compound represented by Formula (1), a compound represented by Formula (2), a compound represented by Formula (3), a compound represented by Formula (4), a compound represented by Formula (5), a compound represented by Formula (6) or a combination thereof,

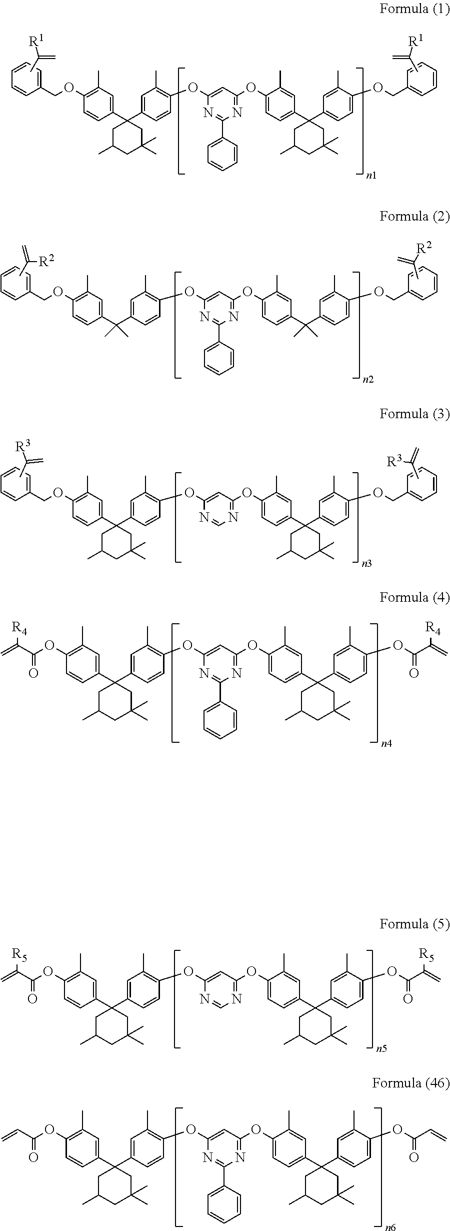

wherein n1 to n6 and R₁ to R₅ are as defined in the specification.

### CROSS-REFERENCE TO RELATED APPLICATIONS

This application claims the benefits of the Taiwan Patent Application Serial Number 114101072, filed on Jan. 10, 2025, the subject matter of which is incorporated herein by reference.

### BACKGROUND OF THE INVENTION

### Field

The present invention provides a resin composition and an article manufactured using the same. More specifically, the present invention provides a resin composition with improved properties and an article manufactured using the same.

### Description of Related Art

Circuit boards (such as printed circuit boards) are one of the necessary components of electronic products, and laminates are one of the key raw materials for making circuit boards. With the rapid development of communication technology, the performance of circuit boards depends on how the resin composition in the laminate is designed. Therefore, how to develop a resin composition suitable for high-performance circuit boards is the direction of the industry's active efforts.

### SUMMARY OF THE INVENTION

In view of the problems encountered in the prior art, in particular, the inability of existing materials to meet one or more of the above performance requirements, the main purpose of the present invention is to provide a resin composition and an article manufactured using the same that can meet the above performance requirements.

The present invention provides a resin composition, comprising: 70 parts by weight of a vinyl-containing resin; 3 parts by weight to 45 parts by weight of a polymer A; and 5 parts by weight to 55 parts by weight of a divinylbenzene-styrene-ethylene terpolymer, wherein the vinyl-containing resin comprises a vinyl-containing polyphenylene ether resin, a maleimide resin, a vinyl-containing polyolefin or a combination thereof, and the polymer A comprises a compound represented by Formula (1), a compound represented by Formula (2), a compound represented by Formula (3), a compound represented by Formula (4), a compound represented by Formula (5), a compound represented by Formula (6) or a combination thereof,

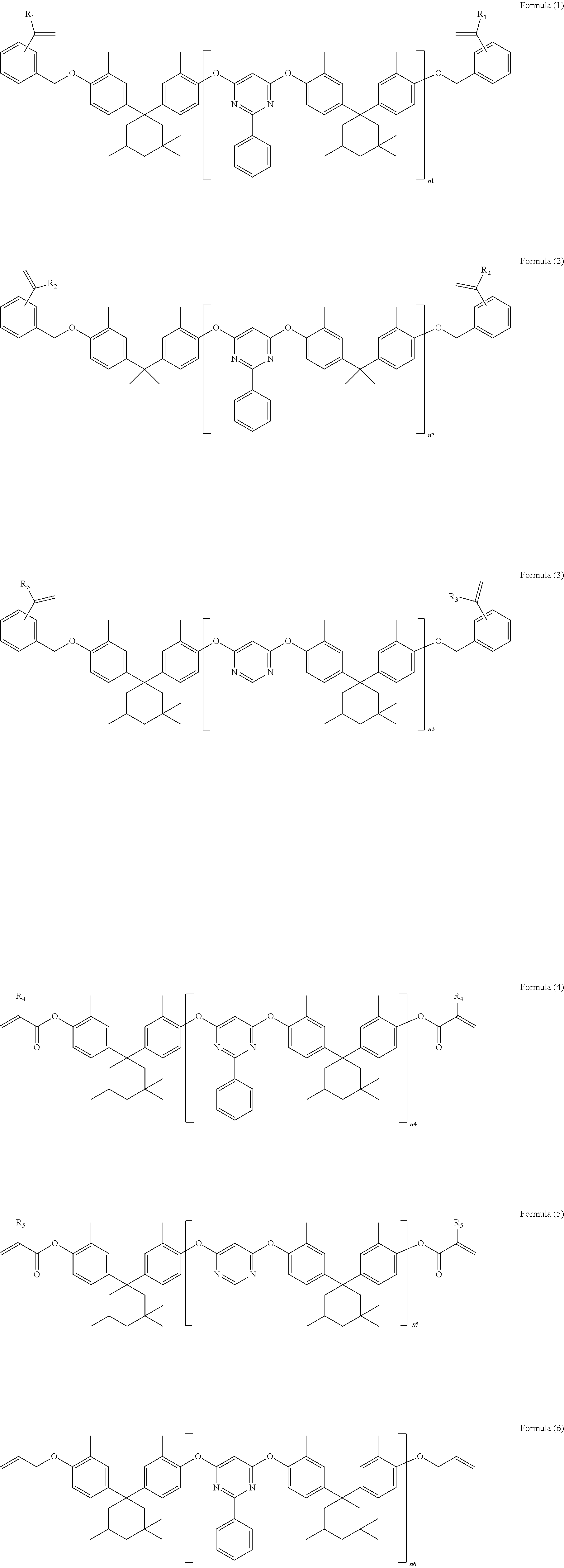

wherein each n1 to n6 independently is a weight average number of repeating units based on a weight average molecular weight (that is, the weight average number of repeating units is determined on the basis of the weight average molecular weight), n1 is a value from 1 to 10, n2 is a value from 1 to 10, n3 is a value from 1 to 10, n4 is a value from 1 to 10, n5 is a value from 1 to 10, n6 is a value from 1 to 10, and each R₁ to R₅ independently is H or C₁ alkyl.

The present invention further provides an article manufactured using the aforesaid resin composition, wherein the article includes a prepreg, a resin film, a laminate or a printed circuit board.

The article manufactured using the resin composition of the present invention, such as a prepreg, a resin film, a laminate or a printed circuit board, has at least one excellent characteristics of the dissipation factor, the reliability, the percent of thermal expansion and the moisture absorption, and therefore can be used to form a high-performance laminate that meet comprehensive needs.

Other novel features of the disclosure will become more apparent from the following detailed description when taken in conjunction with the accompanying drawings.

### BRIEF DESCRIPTION OF DRAWINGS

FIG. 1 is a schematic diagram of a copper-free laminate with elongated bubbles inside.

FIG. 2 is a schematic diagram of a copper-free laminate with elongated bubbles indicated by arrows inside.

FIG. 3 is a schematic diagram of a copper-free laminate without elongated bubbles inside.

### DETAILED DESCRIPTION OF THE INVENTION

In the present specification, the term “a composition comprises A, B and C, wherein A comprises a1, a2 or a3” has the same meaning as the term “a composition comprises A, B and C, wherein A comprises a1, a2, a3 or a combination thereof”, that is “a composition comprises A, B and C, wherein A comprises a1, a2, a3, the combination of a1 and a2, the combination of a1 and a3, the combination of a2 and a3 or the combination of a1, a2 and a3.”

In the present specification, the terms “comprise”, “include”, “have”, “contain” or any other similar terms are open-ended transitional phrases. The terms “consisting of” and “consist” are closed-transitional phrases.

In the present specification, the range “10.0 to 20.0”, “10.0~20.0”, “between 10.0 and 20.0” or “from 10.0 to 20.0” should be deemed to have been specifically disclosed all subranges such as 10.0 to 20.0, 10.0 to 11.0, 15.0 to 20.0, 11.0 to 19.0 etc. The numerical ranges used herein include all possible subranges, i.e., all individual numerical values (including decimals and integers) within the stated ranges.

In the present specification, the numerical values in the present invention include the range of rounding of the significant digits of the numerical values. For example, a value of 2.0 includes a range of 1.95 to 2.04.

In the present specification, “polymer” refers to a product formed by monomers through polymerization reactions. Monomers are compounds that form polymers. In the present specification, “polymer” may include homopolymer (that is a polymer formed by polymerization of a single monomer), copolymer, prepolymer, etc., but is not limited thereto. Copolymers include polymers formed by polymerization of multiple monomers such as dipolymers, terpolymers, and tetrapolymers. For example, dipolymers are formed by polymerization of two different types of monomers, and terpolymers are formed by polymerization of three different types of monomers. Prepolymers are chemical substances produced by the polymerization of two or more compounds with a conversion rate between 10% and 90%. Polymers may also comprise oligomers. Oligomers, also known as low polymers, are polymers composed of 2 to 20 repeating units, usually 2 to 5 repeating units. For example, “diene polymer” includes diene homopolymers, diene copolymers, diene prepolymers, and the like. The term “diene polymer” also includes diene oligomers.

In the present specification, “copolymer” refers to a product formed by polymerization of two or more different monomers, including but not limited to random copolymers (having structures such as but not limited to -AABABBBAAABBA-, wherein A and B respectively represent two monomers with different chemical formulas), alternating copolymers (having structures such as but not limited to: -ABABABAB-), graft copolymers (having structures such as but not limited to:

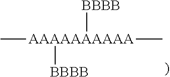

or block copolymers (having structures such as but not limited to: -AAAAA-BBBBBB-AAAAA-). For example, styrene-butadiene copolymer is a product formed by the polymerization of two different monomers: styrene and butadiene. For example, the styrene-butadiene copolymer includes, but is not limited to, a styrene-butadiene random copolymer, a styrene-butadiene alternating copolymer, a styrene-butadiene graft copolymer or a styrene-butadiene block copolymer. The styrene-butadiene block copolymer includes, for example, but is not limited to, a molecular structure of styrene-styrene-styrene-butadiene-butadiene-butadiene-butadiene after polymerization. The styrene-butadiene block copolymer includes, for example, but is not limited to, styrene-butadiene-styrene block copolymer. The styrene-butadiene-styrene block copolymer includes, for example, but is not limited to, a molecular structure of styrene-styrene-styrene-butadiene-butadiene-butadiene-butadiene-styrene-styrene-styrene after polymerization. Similarly, the hydrogenated styrene-butadiene copolymer includes a hydrogenated styrene-butadiene random copolymer, a hydrogenated styrene-butadiene alternating copolymer, a hydrogenated styrene-butadiene graft copolymer or a hydrogenated styrene-butadiene block copolymer. The hydrogenated styrene-butadiene block copolymer includes, for example, but is not limited to, a hydrogenated styrene-butadiene-styrene block copolymer.

In the present specification, “resin” includes monomers, polymers obtained by polymerization of monomers, combinations of monomers, combinations of polymers obtained by polymerization of monomers, or combinations of monomers and polymers obtained by polymerization of monomers, and is not limited thereto. For example, in the present specification, “maleimide resin” includes maleimide monomers, polymers obtained by polymerization of maleimide monomers, combinations of maleimide monomers, combinations of polymers obtained by polymerization of maleimide monomers, or combinations of maleimide monomers and polymers obtained by polymerization of maleimide monomers.

Herein, “vinyl-containing group” includes vinyl group, vinylene group, allyl group, (methyl) acryl group or vinylbenzyl group.

In the present specification, a modified product (also referred to as a modification) includes: a product after the reactive functional groups of each resin are modified, a product after the prepolymerization of each resin with other resins, a product after the crosslinking of each resin with other resins, a product after the homopolymerization of each resin, a product after the copolymerization of each resin with other resins, etc. For example, a product obtained by replacing the original terminal hydroxyl group with a terminal vinyl group through a chemical reaction is a modified product, or a product obtained by chemically reacting the original terminal vinyl group with p-aminophenol to obtain a terminal hydroxyl group is also a modified product.

In the present specification, the “unsaturated bond” described in the present invention refers to an unsaturated bond that is still reactive. For example, vinyl bonds, acetylene bonds, and vinyl bonds on methacrylates are all unsaturated bonds that are still reactive. For example, the unsaturated bond includes, but is not limited to, unsaturated double bonds that can undergo cross-linking reactions with other functional groups. For example, the unsaturated bond includes, but is not limited to, unsaturated carbon-carbon double bonds that can undergo cross-linking reactions with other functional groups.

In the present specification, the (substituent) compound represents both a compound not containing the substituent and a compound containing the substituent. For example, (meth)acrylate should be read as including acrylate and methacrylate.

In the present specification, parts by weight refers to the number of parts by weight, which can be any weight unit, such as but not limited to kilograms, grams, pounds, etc. For example, 100 parts by weight of maleimide resin means it can be 100 kilograms of maleimide resin or 100 pounds of maleimide resin. If the resin solution contains a solvent and a resin, the parts by weight of the (solid or liquid) resin generally refers to the weight unit of the (solid or liquid) resin and does not include the weight unit of the solvent in the solution, while the parts by weight of the solvent refers to the weight unit of the solvent.

The present invention provides a resin composition, comprising: 70 parts by weight of a vinyl-containing resin; 3 parts by weight to 45 parts by weight of a polymer A; and 5 parts by weight to 55 parts by weight of a divinylbenzene-styrene-ethylene terpolymer, wherein the vinyl-containing resin comprises a vinyl-containing polyphenylene ether resin, a maleimide resin, a vinyl-containing polyolefin or a combination thereof, and the polymer A comprises a compound represented by Formula (1), a compound represented by Formula (2), a compound represented by Formula (3), a compound represented by Formula (4), a compound represented by Formula (5), a compound represented by Formula (6) or a combination thereof (the aforesaid combination thereof may also be called as a mixture thereof),

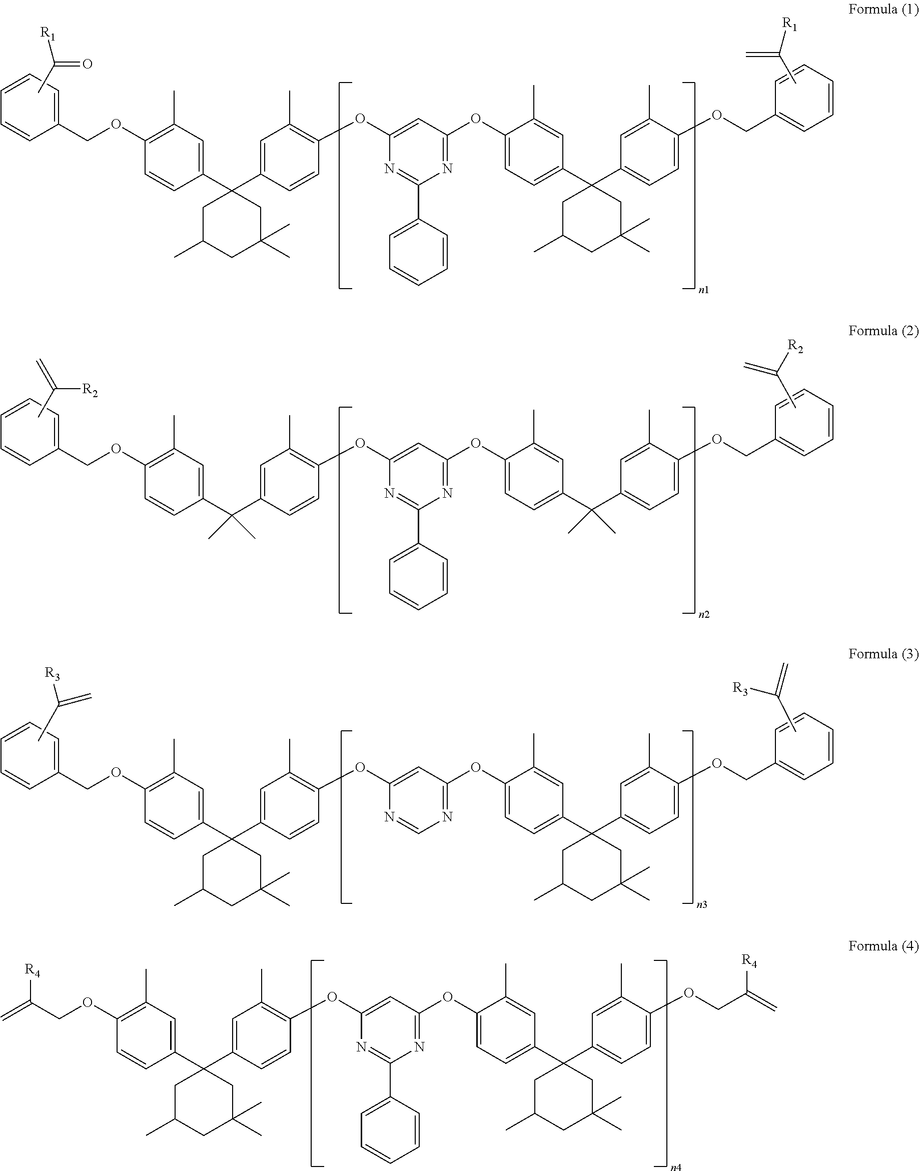

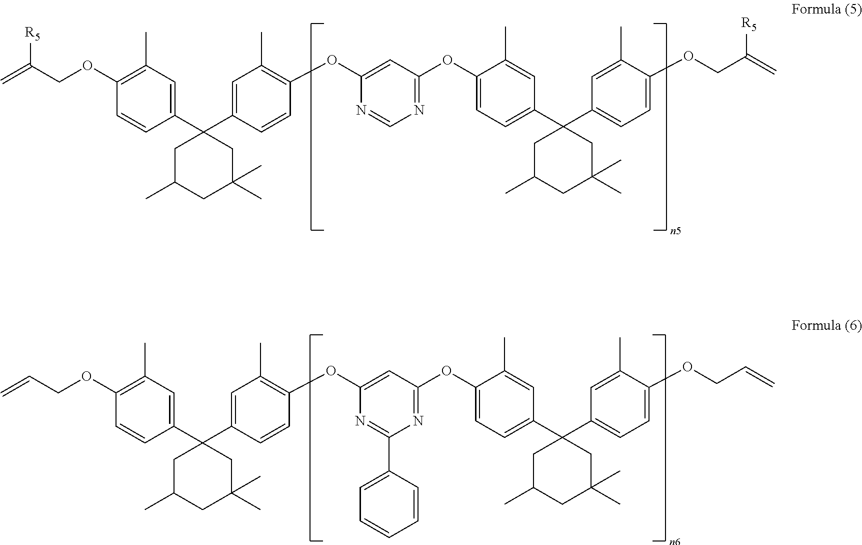

wherein each n1 to n6 independently is a weight average number of repeating units based on a weight average molecular weight, n1 is a value from 1 to 10, n2 is a value from 1 to 10, n3 is a value from 1 to 10, n4 is a value from 1 to 10, n5 is a value from 1 to 10, n6 is a value from 1 to 10, and each R₁ to R₅ independently is H or C₁ alkyl.

In one embodiment, each R₁ to R₅ independently, for example, is H or methyl.

In one embodiment, the compound represented by Formula (1) comprises a compound represented by Formula (1-1), a compound represented by Formula (1-2) or a combination thereof:

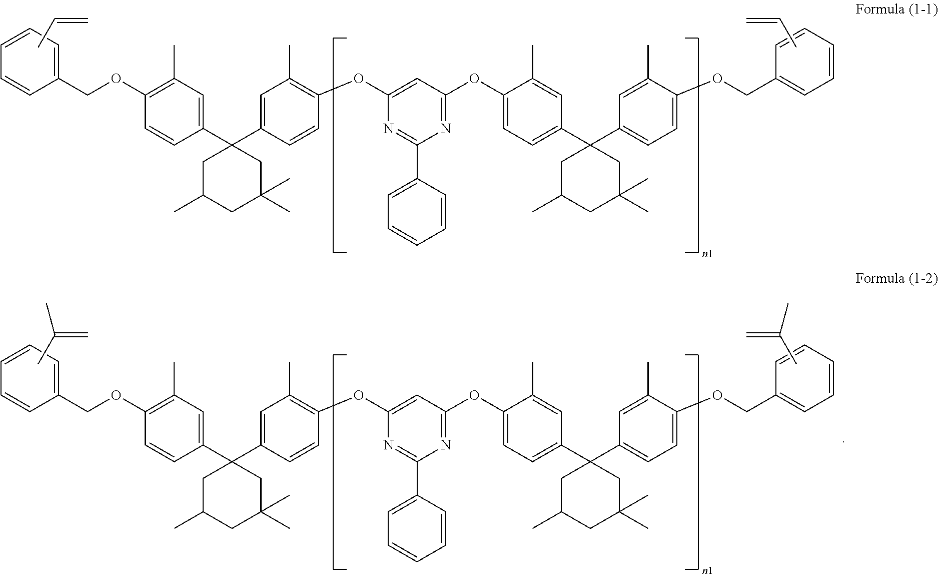

In one embodiment, the compound represented by Formula (1-1) comprises a compound represented by Formula (1-1-1), a compound represented by Formula (1-1-2), a compound represented by Formula (1-1-3) or a combination thereof:

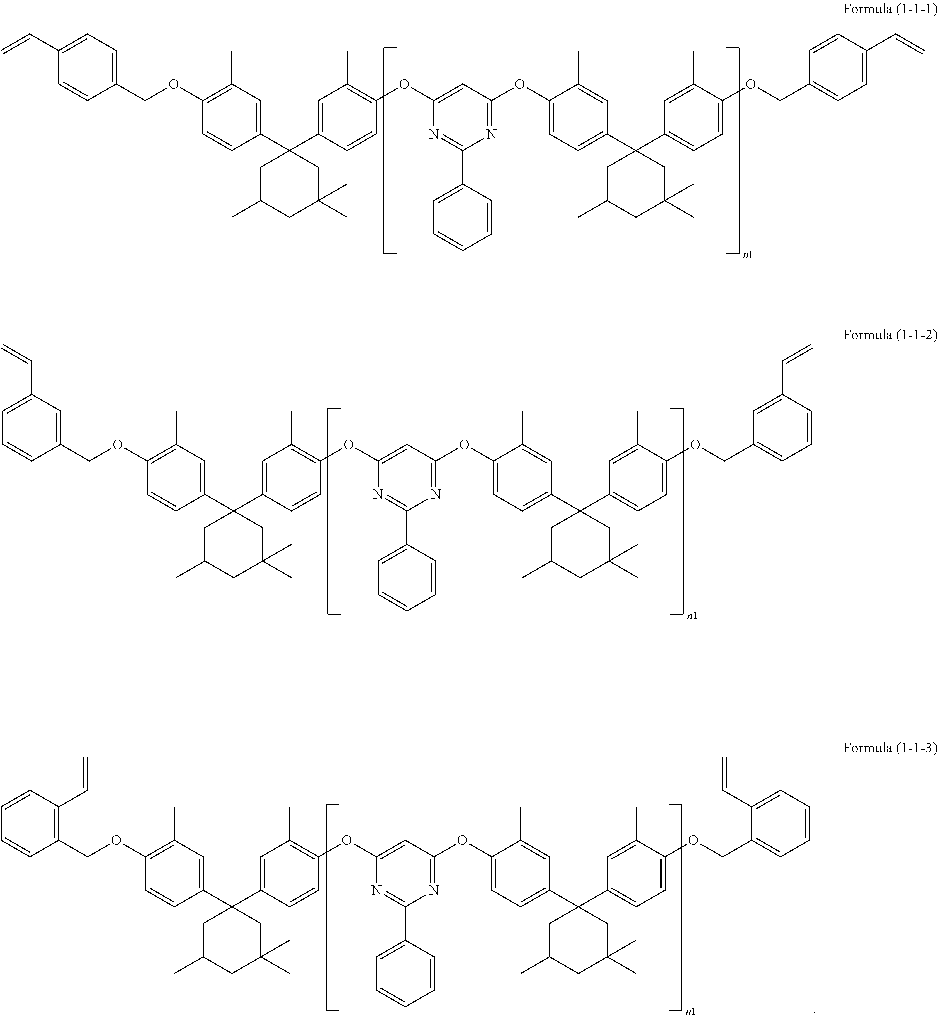

In one embodiment, the compound represented by Formula (1-2) comprises a compound represented by Formula (1-2-1), a compound represented by Formula (1-2-2), a compound represented by Formula (1-2-3) or a combination thereof:

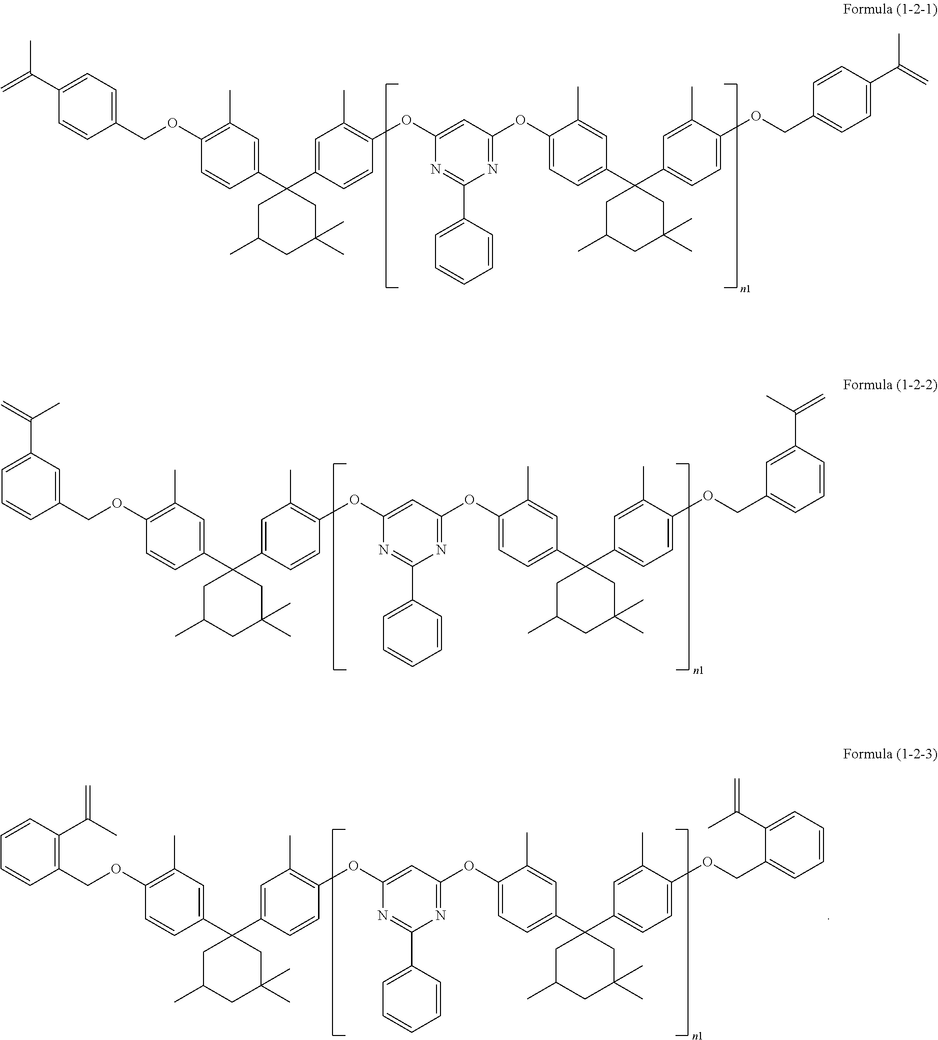

Similarly, although not explicitly shown here, the compounds represented by Formula (2) to Formula (5) may also have various aspects like the compound represented by Formula (1). More specifically, R₂ in Formula (2) may be H or methyl, and each (R₂)-vinyl group of Formula (2) respectively have ortho, meta or para substitution. R₃ in Formula (3) may be H or methyl, and each (R₃)-vinyl group in Formula (3) respectively have ortho, meta or para substitution. R₄ in Formula (4) may be H or methyl. R₅ in Formula (5) may be H or methyl.

For example, in one embodiment, the compound represented by Formula (2) may be a compound represented by Formula (2-1-2), but the present invention is not limited thereto.

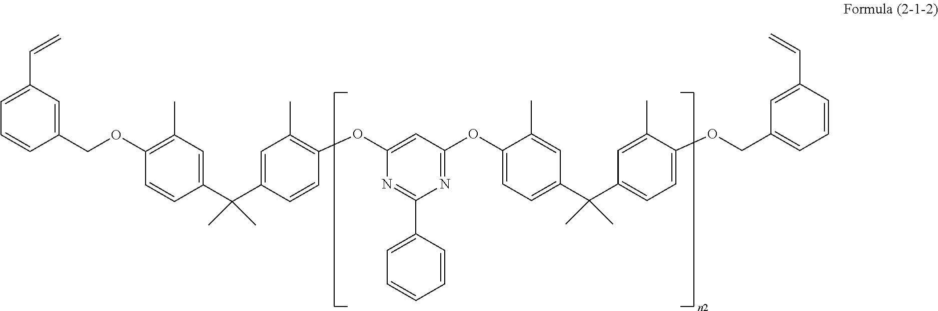

For example, in one embodiment, the compound represented by Formula (3) may be a compound represented by Formula (3-1-2), a compound represented by Formula (3-2-2) or a combination thereof (also called as a mixture thereof), but the present invention is not limited thereto.

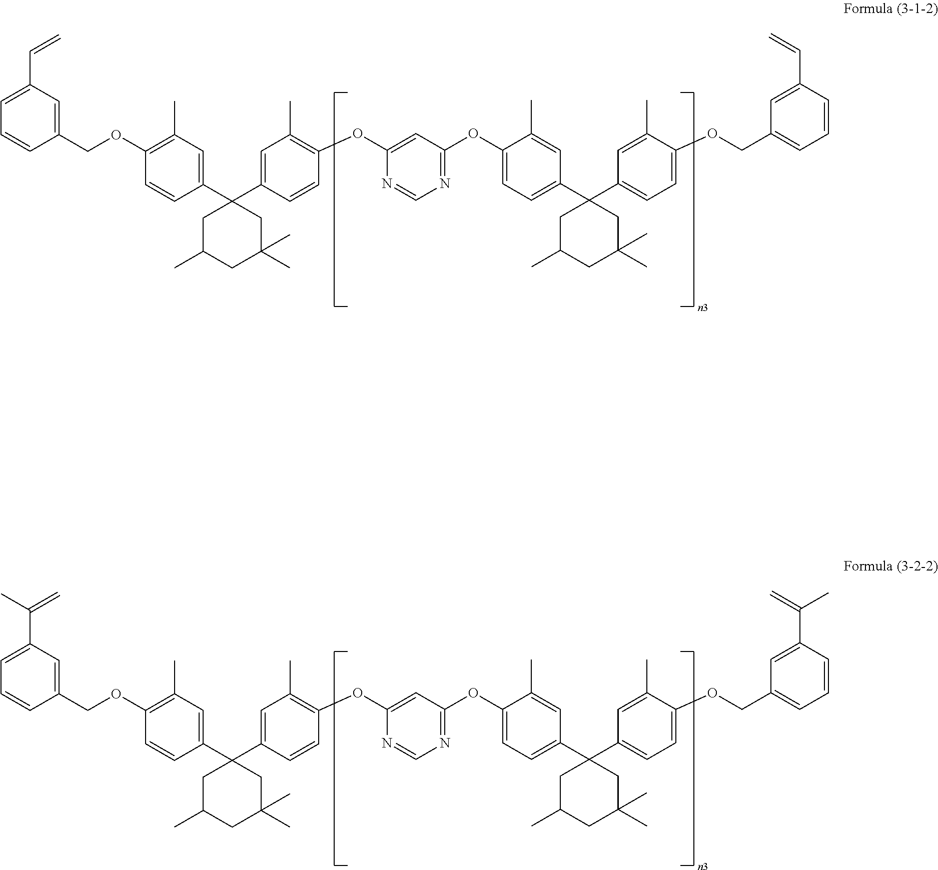

For example, in one embodiment, the compound represented by Formula (4) may be a compound represented by Formula (4-2), but the present invention is not limited thereto.

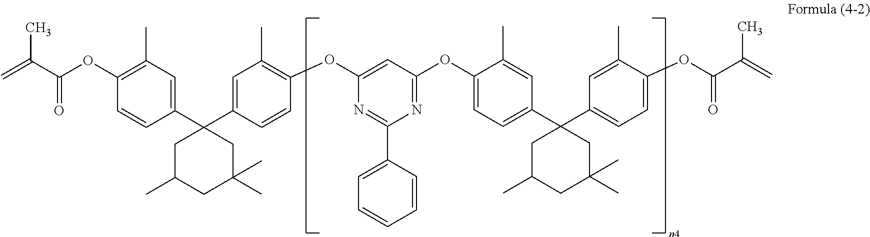

For example, in one embodiment, the compound represented by Formula (5) may be a compound represented by Formula (5-1), a compound represented by Formula (5-2) or a mixture thereof, but the present invention is not limited thereto.

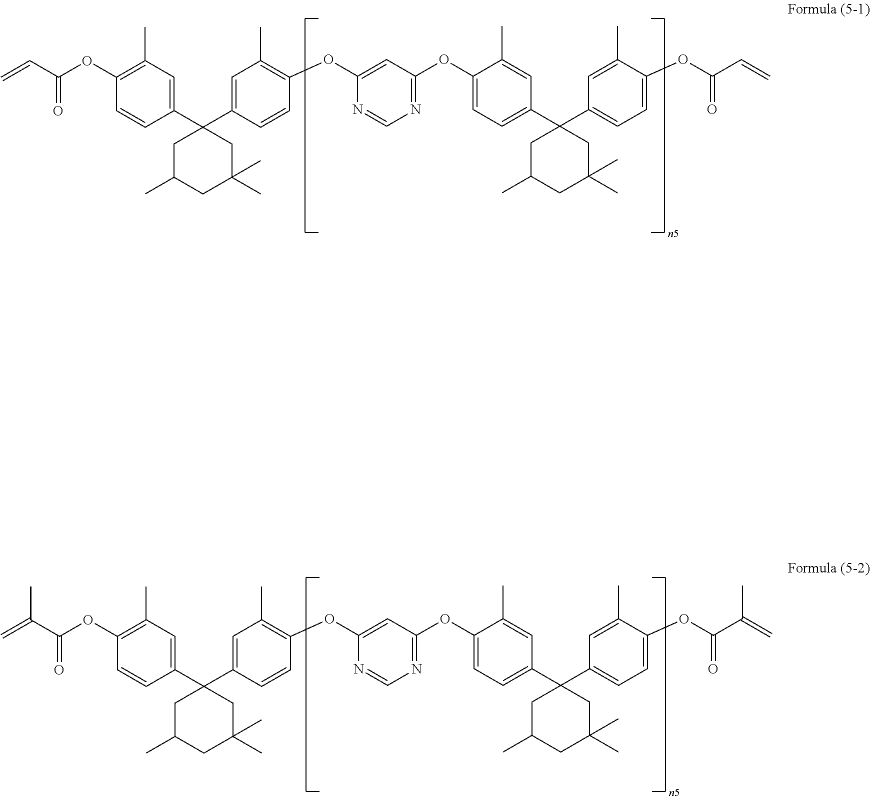

In one embodiment, in Formula (1) to Formula (6), each n1 to n6 independently represent weight average number of repeating units based on a weight average molecular weight in the brackets. That is, the polymerization degrees n (for example, n1 to n6) of the repeating units of the compounds represented by Formula (1) to Formula (6) is calculated from the measured value of the weight average molecular weight (Mw) of the compounds represented by Formula (1) to Formula (6) to obtain the weight average number of repeating units. Thus, each n1 to n6 independently is a value from 1 to 10, for example, each n1 to n6 independently is a positive integer from 1 to 10, or each n1 to n6 independently is a non-integer from 1 to 10. For example, in one embodiment, each n1 to n6 independently is 0.5, 0.6, 1, 1.1, 2.3, 3, 4.5, 5, 7, 8.8, 9.1, 10 or 10.4, but the present invention is not limited thereto.

In one embodiment, the weight average molecular weight of the compound represented by Formula (1) to Formula (6) may range from 1,000 to 5,000 respectively. In another embodiment, the weight average molecular weight of the compound represented by Formula (1) to Formula (6) may range from 1,000 to 4,000 respectively.

In one embodiment, the compounds represented by Formula (1) to Formula (6) can be commercially available.

In one embodiment, the divinylbenzene-styrene-ethylene terpolymer in the resin composition may be a product including three monomers of divinylbenzene, styrene and ethylene obtained by polymerization of three monomer raw materials, namely, divinylbenzene, styrene and ethylene. The above divinylbenzene-styrene-ethylene terpolymer obtained by the polymerization may be a random polymer, that is, a polymer obtained by cross-linking the three monomers of divinylbenzene, styrene and ethylene with each other through a random arrangement. In one embodiment, the divinylbenzene in the monomer raw material of the divinylbenzene-styrene-ethylene terpolymer may be, for example, p-divinylbenzene.

In one embodiment, the number average molecular weight of the divinylbenzene-styrene-ethylene terpolymer (Mn) may range from 5,000 to 15,000. In another embodiment, the number average molecular weight of the divinylbenzene-styrene-ethylene terpolymer may range from 5,000 to 11,000. In further another embodiment, the number average molecular weight of the divinylbenzene-styrene-ethylene terpolymer may range from 6,000 to 10,000.

In one embodiment, the aforesaid divinylbenzene-styrene-ethylene terpolymer is obtained by polymerization of a mixture, and the mixture comprises 40 mol % to 80 mol % of an ethylene monomer, 20 mol % to 60 mol % of a styrene monomer and 0.01 mol % to 10 mol % of a divinylbenzene monomer, and a total amount of the ethylene monomer, the styrene monomer and the divinylbenzene monomer is 100 mol %. In one embodiment, the aforesaid divinylbenzene-styrene-ethylene terpolymer may be formed by polymerization of a mixture, and the mixture comprises 39.99 mol % to 80 mol % of an ethylene monomer, 19.99 mol % to 60 mol % of a styrene monomer and 0.01 mol % to 10 mol % of a divinylbenzene monomer, and a total amount of the ethylene monomer, the styrene monomer and the divinylbenzene monomer is 100 mol %. In another embodiment, the aforesaid divinylbenzene-styrene-ethylene terpolymer may be formed by polymerization of a mixture, and the mixture comprises 60 mol % to 80 mol % of an ethylene monomer, 19.99 mol % to 30 mol % of a styrene monomer and 0.01 mol % to 10 mol % of a divinylbenzene monomer, and a total amount of the ethylene monomer, the styrene monomer and the divinylbenzene monomer is 100 mol %.

In another embodiment, in the polymerization raw materials of the divinylbenzene-styrene-ethylene terpolymer, the amount of the ethylene may be about 40 mol % to 80 mol %, the amount of the styrene may be about 20 mol % to 60 mol %, the amount of the divinylbenzene may be about 0.01 mol % to 10 mol %, and a total amount of the divinylbenzene, the styrene, and the ethylene is 100 mol %. In other embodiments, in the polymerization raw materials of the divinylbenzene-styrene-ethylene terpolymer, the amount of the ethylene may be about 40 mol % to 80 mol %, the amount of the styrene may be about 20 mol % to 60 mol %, the amount of the divinylbenzene may be about 0.01 mol % to 1 mol %, and a total amount of the divinylbenzene, the styrene, and the ethylene is 100 mol %. In one embodiment, in the polymerization raw materials of the divinylbenzene-styrene-ethylene terpolymer, the amount of the ethylene may be about 39.99 mol % to 80 mol %, the amount of the styrene may be about 19.99 mol % to 60 mol %, the amount of the divinylbenzene may be about 0.01 mol % to 10 mol %, and a total amount of the divinylbenzene, the styrene, and the ethylene is 100 mol %. In other embodiments, in the polymerization raw materials of the divinylbenzene-styrene-ethylene terpolymer, the amount of the ethylene is 80 mol %, the amount of the styrene is 19.99 mol % (according to the above description, the value 19.99 can be represented by the value 20, that is, 20 mol %), the amount of the divinylbenzene is 0.01 mol %, and a total amount of the ethylene, the styrene, and the divinylbenzene is 100 mol %. In other embodiments, in the polymerization raw materials of the divinylbenzene-styrene-ethylene terpolymer, the amount of the ethylene is 39.99 mol % (according to the above description, the value 39.99 can be represented by the value 40, that is, 40 mol %), the amount of the styrene is 60 mol %, the amount of the divinylbenzene is 0.01 mol %, and a total amount of the ethylene, the styrene and the divinylbenzene is 100 mol %. In other embodiments, in the polymerization raw materials of the divinylbenzene-styrene-ethylene terpolymer, the amount of the ethylene may be about 60 mol % to 80 mol %, the amount of the styrene may be about 20 mol % to 30 mol %, the amount of the divinylbenzene may be about 0.01 mol % to 10 mol %, and a total amount of the divinylbenzene, the styrene, and the ethylene is 100 mol %. In other embodiments, in the polymerization raw materials of the divinylbenzene-styrene-ethylene terpolymer, the amount of the ethylene may be 60 mol % to 80 mol %, the amount of the styrene may be 19.99 mol % to 30 mol %, the amount of the divinylbenzene may be 0.01 mol % to 10 mol %, and a total amount of the divinylbenzene, the styrene, and the ethylene is 100 mol %. In other embodiments, in the polymerization raw materials of the divinylbenzene-styrene-ethylene terpolymer, the amount of the ethylene may be about 70 mol % to 80 mol %, the amount of the styrene may be about 20 mol % to 30 mol %, the amount of the divinylbenzene may be about 0.01 mol % to 1 mol %, and a total amount of the divinylbenzene, the styrene, and the ethylene is 100 mol %. In other embodiments, in the polymerization raw materials of the divinylbenzene-styrene-ethylene terpolymer, the amount of the ethylene may be 69.99 mol % to 80 mol %, the amount of the styrene may be 19.99 mol % to 30 mol %, the amount of the divinylbenzene may be 0.01 mol % to 1 mol %, and a total amount of the divinylbenzene, the styrene, and the ethylene is 100 mol %.

In one embodiment, the content of the vinyl-containing resin in the resin composition is 70 parts by weight, the content of other resins or additives is related to 70 parts by weight of the vinyl-containing resin. For example, in one embodiment of the present invention, with respect to 70 parts by weight of the vinyl-containing resin, the content of the polymer A may be 3 parts by weight to 45 parts by weight. Similarly, in one embodiment of the present invention, with respect to 70 parts by weight of the vinyl-containing resin (for example, 70 parts by weight of the vinyl-containing polyphenylene ether resin), the content of the divinylbenzene-styrene-ethylene terpolymer may be 5 parts by weight to 55 parts by weight. For example, in one embodiment of the present invention, the resin composition may comprise 70 kg of the vinyl-containing polyphenylene ether resin, 3 kg to 45 kg of the polymer A, and 5 kg to 55 kg of the divinylbenzene-styrene-ethylene terpolymer. For example, in one embodiment of the present invention, the resin composition may comprise 70 lbs of the vinyl-containing polyphenylene ether resin, 3 lbs to 45 lbs of the compound represented by Formula (1), and 5 lbs to 55 lbs of the divinylbenzene-styrene-ethylene terpolymer. For example, in one embodiment of the present invention, the resin composition may comprise a total amount of 70 lbs of the vinyl-containing polyphenylene ether resin, maleimide resin and vinyl-containing polyolefin, 3 lbs to 45 lbs of the compound represented by Formula (1), and 5 lbs to 55 lbs of the divinylbenzene-styrene-ethylene terpolymer.

In one embodiment, the vinyl-containing polyphenylene ether resin may include various polyphenylene ether resins with terminal vinyl modification. The vinyl-containing polyphenylene ether resin may comprise vinylbenzyl-containing polyphenylene ether resin, (meth)acrylate-containing polyphenylene ether resin or a combination thereof, but the present invention is not limited thereto. Vinyl-containing polyphenylene ether resins with vinylbenzyl or (meth)acrylate at the terminal can be polymerized through unsaturated bonds.

In one embodiment, the vinyl-containing polyphenylene ether resin may comprise various vinyl-containing polyphenylene ether resins known in the art. The vinyl-containing polyphenylene ether resin suitable for the present invention is not particularly limited and may be any one or more commercially available products or homemade products. In some embodiments, one or more of the following vinyl-containing polyphenylene ether resins can be used: vinylbenzyl biphenyl polyphenyl ether resin (e.g., OPE-2st, available from Mitsubishi Gas Chemical Co., Ltd.), methacrylate polyphenylene ether resin (e.g., SA9000, available from Sabic Corporation) or polyphenylene ether resin containing vinyl benzyl bisphenol A. However, the present invention is not limited thereto.

In one embodiment, examples of the maleimide resin in the resin composition may comprise, but not limited to, 4,4′-diphenylmethane bismaleimide, polyphenylmethane maleimide (or also called as oligomer of phenylmethane maleimide), bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl) hexane, N-2,3-xylylmaleimide, N-2,6-xylylmaleimide, N-phenylmaleimide, vinyl benzyl maleimide, biphenyl-containing maleimide, xylok-containing maleimide, indane-containing maleimide, maleimide resin containing C₁₀₋₅₀ aliphatic structure, prepolymer of diallyl compound and maleimide resin, prepolymer of multifunctional amine and maleimide resin (herein, the multifunctional amine includes two or more amine groups), prepolymer of aminophenol and maleimide resin, or a combination thereof.

For example, specific examples of maleimide resin may comprise but not limited to: maleimide resin produced by Daiwakasei Industry with trade names BMI-1000, BMI-1000H, BMI-1100, BMI-1100H, BMI-2000, BMI-2300, BMI-3000, BMI-3000H, BMI-4000, BMI-5000, BMI-5100, BMI-TMH, BMI-7000 and BMI-7000H; maleimide resin produced by K.I Chemical Co., Ltd. with trade names BMI-70 and BMI-80; or maleimide resin produced by Nippon Kayaku Co., Ltd. with trade names MIR-3000 or MIR-5000.

For example, specific examples of maleimide resin containing C₁₀₋₅₀ aliphatic structure may comprise but not limited to: maleimide resin containing C₁₀₋₅₀ aliphatic structure produced by Designer Molecular Co., Ltd. with trade names BMI-689, BMI-1400, BMI-1500, BMI-1700, BMI-2500, BMI-3000, BMI-5000 and BMI-6000; or maleimide resin containing C₁₀₋₅₀ aliphatic structure produced by Shin-etsu chemical co., Ltd. with trade names SLK-3000 series, SLK-1500 series and SLK-2000 series. The structure of SLK-3000 produced by Shin-etsu chemical co., Ltd. is the same as the structure of BMI-3000 produced by Designer Molecular Co., Ltd.

In one embodiment, the vinyl-containing polyolefin comprised in the resin composition refers to other types of vinyl-containing polyolefin other than the divinylbenzene-styrene-ethylene terpolymer, which may comprise, for example, but is not limited to polybutadiene, polyisoprene, styrene-butadiene copolymer, styrene-isoprene copolymer, divinylbenzene-styrene-butadiene terpolymer, butadiene styrene copolymer adducted with maleic anhydride, vinyl-polybutadiene-urethane oligomer, or polybutadiene adducted with maleic anhydride.

In one embodiment, with respect to 70 parts by weight of the vinyl-containing resin, the content of the aforesaid vinyl-containing polyolefin other than the divinylbenzene-styrene-ethylene terpolymer may be 0.1 parts by weight to 50 parts by weight, for example, may be 0.1 parts by weight to 20 parts by weight, 0.4 parts by weight to 19 parts by weight, 0.1 parts by weight to 5 parts by weight or 4 parts by weight to 19 parts by weight, but the present invention is not limited thereto. In further another embodiment, the resin composition may not comprise the vinyl-containing polyolefin other than the divinylbenzene-styrene-ethylene terpolymer, that is, the content of the vinyl-containing polyolefin other than the divinylbenzene-styrene-ethylene terpolymer is 0 parts by weight, which means that the vinyl-containing polyolefin other than the divinylbenzene-styrene-ethylene terpolymer is not intentionally added into the resin composition.

In one embodiment, the resin composition may selectively further comprise a hydrogenated polyolefin. For example, the hydrogenated polyolefin may comprise hydrogenated polybutadiene, hydrogenated styrene-butadiene-styrene block copolymer (also known as styrene-ethylene/butylene-styrene copolymer) or hydrogenated styrene-butadiene-styrene block copolymer adducted with maleic anhydride. The hydrogenated polyolefin of the present invention may be any one or more commercially available products or homemade products. That is, the hydrogenated polyolefin may comprise unsubstituted hydrogenated polybutadiene, unsubstituted hydrogenated styrene-butadiene-styrene triblock copolymer or hydrogenated styrene-butadiene-styrene triblock copolymer adducted with maleic anhydride addition. For example, the hydrogenated polyolefin may comprise, but not limited to, hydrogenated polyolefin produced by Asahi KASEI corporation with trade names H1221, H1062, H1521, H1052, H1041, H1053, H1051, H1517, H1043, N504, H1272, M1943, M1911 or M1913, hydrogenated polyolefin produced by KRATON corporation with trade names G1650, G1651, G1652, G1654, G1657, G1726, FG1901 or FG1924, or hydrogenated polyolefin produced by Kuraray Co., Ltd with trade names 8004, 8006 or 8007L. The hydrogenated polybutadiene may comprise, but not limited to, the hydrogenated polybutadiene produced by Nippon Soda with trade names BI-1000, BI-2000, BI-3000 or BI-3040.

In one embodiment, when the resin composition comprises hydrogenated polyolefin, the content of the hydrogenated polyolefin may be 0.1 parts by weight to 50 parts by weight, and for example, may be 1 parts by weight to 50 parts by weight or 15 parts by weight to 38 parts by weight, but the present invention is not limited thereto, and the content of the polyolefin may be adjusted according to the needs. In further another embodiment, the resin composition may not comprise hydrogenated polyolefin, that is, the content of the hydrogenated polyolefin is 0 parts by weight, which means that the hydrogenated polyolefin is not intentionally added into the resin composition.

In one embodiment, the resin composition may selectively further comprise acrylate, triallyl isocyanurate (TAIC), triallyl cyanurate, styrene maleic anhydride copolymer resin, phenol resin, benzophenone resin, cyanate resin, polysiloxane resin, polyester resin, epoxy resin, polyamide resin, polyimide resin or a combination thereof.

In one embodiment, the resin composition may selectively further comprise acrylate. For example, the acrylate used in the present invention comprise, but not limited to, tricyclodecane di(meth)acrylate, tri(meth)acrylate, 1,1′-[(octahydro-4,7-methylene-1H-indene-5,6-diyl)bis(methylene)]ester or a combination thereof.

In one embodiment, with respect to 70 parts by weight of the vinyl-containing resin, the resin composition may further comprise 1 part by weight to 5 parts by weight of acrylate, for example, 1 part by weight to 3 parts by weight, but the present invention is not limited thereto. In one embodiment, the resin composition may not comprise acrylate, and that is, the content of the acrylate is 0 parts by weight, which means that the acrylate is not intentionally added into the resin composition. However, the present invention is not limited thereto, and the content of the acrylate may be adjusted according to the needs.

In one embodiment, the resin composition may selectively further comprise triallyl isocyanurate. In one embodiment, with respect to 70 parts by weight of the vinyl-containing resin, the resin composition may further comprise 3 parts by weight to 20 parts by weight of triallyl isocyanurate, and for example, 3 parts by weight to 15 parts by weight, 5 parts by weight to 15 parts by weight, 3 parts by weight to 10 parts by weight or 3 parts by weight to 5 parts by weight, but the present invention is not limited thereto. In another embodiment, the resin composition may not comprise triallyl isocyanurate, that is, the content of the triallyl isocyanurate is 0 parts by weight, which means that the triallyl isocyanurate is not intentionally added into the resin composition. However, the present invention is not limited thereto, and the content of the triallyl isocyanurate can be adjusted according to the needs.

In one embodiment, the resin composition may selectively further comprise triallyl cyanurate. In one embodiment, the content of triallyl cyanurate is not particularly limited. In another embodiment, the resin composition may not comprise triallyl cyanurate, and that is, the content of the triallyl cyanurate is 0 parts by weight, which means that the triallyl cyanurate is not intentionally added into the resin composition. However, the present invention is not limited thereto, and the content of the triallyl cyanurate can be adjusted according to the needs.

In one embodiment, the resin composition may selectively further comprise styrene maleic anhydride copolymer resin (styrene maleic anhydride resin for short). In one embodiment, in the styrene maleic anhydride copolymer resin, a ratio of styrene to maleic anhydride may be 1:1, 2:1, 3:1, 4:1, 6:1 or 8:1. Specific examples of the styrene maleic anhydride copolymer resin may comprise, but not limited to, styrene maleic anhydride copolymer produced by Cray Valley with trade names SMA-1000, SMA-2000, SMA-3000, EF-30, EF-40, EF-60 and EF-80, or styrene maleic anhydride copolymer produced by Polyscope Corporation with trade names C400, C500, C700 and C900. Styrene maleic anhydride resin may be esterified styrene maleic anhydride copolymer, for example, esterified styrene maleic anhydride copolymer produced by Cray Valley with trade names SMA1440, SMA17352, SMA2625, SMA3840 and SMA31890.

In one embodiment, the content of the styrene maleic anhydride copolymer resin is not particularly limited. In one embodiment, the resin composition may not comprise styrene maleic anhydride resin, and that is, the content of the styrene maleic anhydride resin is 0 parts by weight. However, the present invention is not limited thereto, and the content of the styrene maleic anhydride resin can be adjusted according to the needs.

In one embodiment, the resin composition may selectively further comprise benzoxazine resin. In one embodiment, the benzoxazine resin may be, for example, bisphenol A type benzoxazine resin, bisphenol F type benzoxazine resin, phenolphthalein type benzoxazine resin, dicyclopentadiene benzoxazine resin or phosphorus-containing benzoxazine resin. Specific examples of the benzoxazine resin may comprise, but not limited to, phenolphthalein type benzoxazine resin produced by Huntsman with trade name LZ-8270, bisphenol F type benzoxazine resin produced by Huntsman with trade name LZ-8280, bisphenol A type benzoxazine resin produced by Huntsman with trade name LZ-8290 or resin produced by Showa Polymer Corporation with trade name HFB-2006M.

In one embodiment, the content of the benzoxazine resin is not particularly limited. In one embodiment, the resin composition may not comprise the benzoxazine resin, and that is, the content of the benzoxazine resin is 0 parts by weight. However, the present invention is not limited thereto, and the content of the benzoxazine resin can be adjusted according to the needs.

In one embodiment, the resin composition may selectively further comprise cyanate ester resin. For example, the cyanate ester resin may comprise phenol novolac type cyanate ester resin, bisphenol A type cyanate ester resin, bisphenol A novolac type cyanate ester resin, bisphenol F type cyanate ester resin, bisphenol F novolac type cyanate ester resin, cyanate ester resin containing dicyclopentadiene structure, cyanate ester resin containing naphthalene ring structure or phenolphthalein type cyanate ester resin. Specific examples of the cyanate ester resin may comprise, but not limited to cyanate ester resin produced by Lonza with trade names Primaset PT-15, PT-30S, PT-60S, BA-200, BA-230S, BA-3000S, BTP-2500, BTP-6020S, DT-4000, DT-7000, ULL950S, HTL-300, CE-320, LVT-50 or LeCy.

In one embodiment, the content of the cyanate ester resin is not particularly limited. In another embodiment, the resin composition may not comprise cyanate ester resin, and that is, the content of the cyanate ester resin is 0 parts by weight. However, the present invention is not limited thereto and the content of the cyanate ester resin can be adjusted according to the needs.

In one embodiment, the resin composition may selectively further comprise polysiloxane resin (hereinafter referred to as polysiloxane). Specific examples of the polysiloxane may comprise, but not limited to, polysiloxane produced by Shin-etsu chemical co., Ltd. with trade names X-22-161A, X-22-161B, X-22-163A, X-22-163B, or X-22-164. In one embodiment, the content of the polysiloxane is not particularly limited. In another embodiment, the resin composition may not comprise polysiloxane, and that is, the content of the polysiloxane is 0 parts by weight, which means that the polysiloxane is not intentionally added into the resin composition. However, the present invention is not limited thereto, and the content of the polysiloxane can be adjusted according to the needs.

In one embodiment, the resin composition may selectively further comprise divinylbiphenyl (DVBP). In one embodiment, with respect to 70 parts by weight of the vinyl-containing resin, the resin composition may further comprise 0.1 parts by weight to 10 parts by weight of the divinylbiphenyl, and for example, may further comprise 1 part by weight to 10 parts by weight, 1 part by weight to 5 parts by weight or 2 parts by weight to 3 parts by weight of the divinylbiphenyl, but the present invention is not limited thereto. In another embodiment, the resin composition may not comprise the divinylbiphenyl, and that is, the content of the divinylbiphenyl is 0 parts by weight, which means that the divinylbiphenyl is not intentionally added into the resin composition. However, the present invention is not limited thereto, and the content of the divinylbiphenyl can be adjusted according to the needs.

In one embodiment, the resin composition may selectively further comprise diallyl isophthalate (DAIP). In one embodiment, with respect to 70 parts by weight of the vinyl-containing resin, the resin composition may further comprise 0.1 parts by weight to 10 parts by weight of the diallyl isophthalate, and for example, may comprise 1 part by weight to 10 parts by weight, 1 part by weight to 5 parts by weight or 2 parts by weight to 3 parts by weight of the diallyl isophthalate, but the present invention is not limited thereto. In another embodiment, the resin composition may not comprise diallyl isophthalate, and that is, the content of the diallyl isophthalate is 0 parts by weight, which means that the diallyl isophthalate is not intentionally added into the resin composition. However, the present invention is not limited thereto, and the content of the diallyl isophthalate can be adjusted according to the needs.

In one embodiment, the resin composition may further include an inorganic filler, an initiator, an inhibitor, a flame retardant, a colorant, a toughening agent, a core-shell rubber, a silane coupling agent, a solvent or a combination thereof. The aforementioned components may be used alone or in combination.

In one embodiment, the resin composition may selectively further comprise an inorganic filler, and the content of the inorganic filler is not particularly limited. In another embodiment, with respect to 70 parts by weight of the vinyl-containing resin, the resin composition may further comprise 5 parts by weight to 380 parts by weight of the inorganic filler, 60 parts by weight to 240 parts by weight of the inorganic filler, 160 parts by weight to 360 parts by weight of the inorganic filler or 130 parts by weight to 265 parts by weight of the inorganic filler. However, the present invention is not limited thereto, and the content of the inorganic filler can be adjusted according to the needs.

In one embodiment, the inorganic filler may be silicon dioxide. In one embodiment, the inorganic filler may be spherical silica. The spherical silica may include various types of spherical silica known in the art, and the particle size distribution D50 of the spherical silica may be, for example, less than or equal to 2.0 μm. For example, the particle size distribution D50 may preferably range from 0.2 μm to 2.0 μm, for example, but not limited to 0.2 μm, 0.3 μm, 0.4 μm, 0.6 μm, 0.8 μm, 1.2 μm, 1.3 μm or 2.0 μm. For example, the particle size distribution D50 refers to the particle size corresponding to the cumulative volume distribution of fillers (such as but not limited to spherical silica) reaching 50% as measured by laser scattering. The spherical silica suitable for the present invention is not particularly limited, and may be any one or more commercially available products, such as but not limited to spherical silica purchased from Admatechs Company.

In one embodiment, with respect to 70 parts by weight of the vinyl-containing resin, the inorganic filler may comprise 120 parts by weight to 360 parts by weight of the spherical silica, 160 parts by weight to 360 parts by weight of the spherical silica, 240 parts by weight to 360 parts by weight of the spherical silica or 130 parts by weight to 265 parts by weight of the spherical silica. However, the present invention is not limited thereto, and the content of the spherical silica may be adjusted according to the needs.

In one embodiment, the spherical silica may optionally be pretreated with siloxane if it is needed. Siloxane may comprise amino silane, epoxide silane, vinyl silane, ester silane, hydroxysilane, isocyanurate silane, methacryloxysilane or acryloxysilane. With respect to 100 parts by weight of the spherical silica, the amount of the aforesaid siloxane for pretreatment may range from 0.005 parts by weight to 0.5 parts by weight, but the present invention is not limited thereto. The amount of the siloxane is not particularly limited, and the amount of the siloxane may be adjusted according to the dispersion of the inorganic filler in the resin composition.

In one embodiment, the inorganic filler in the resin composition may be an inorganic filler other than the spherical silica. In one embodiment, the inorganic filler other than spherical silica may include non-spherical silica (i.e., conventional irregular silica, which is not spherical), aluminum oxide, aluminum hydroxide, magnesium oxide, magnesium hydroxide, calcium carbonate, aluminum nitride, boron nitride, aluminum silicon carbide, silicon carbide, titanium dioxide, barium titanate, lead titanate, strontium titanate, calcium titanate, magnesium titanate, barium zirconate, lead zirconate, magnesium zirconate, lead zirconate titanate, zinc molybdate, calcium molybdate, magnesium molybdate, ammonium molybdate, zinc molybdate-modified talc, zinc oxide, zirconium oxide, mica, boehmite (AlOOH), calcined talc, talc, silicon nitride or calcined kaolin.

In addition, except for the aforementioned non-spherical silicon dioxide, the remaining aforementioned inorganic fillers other than the spherical silica may be spherical, fibrous, plate-like, granular, flake-like or needle-like. The inorganic filler other than spherical silica can be selectively pretreated with a siloxane compound if it is needed. The examples and amounts of siloxane compounds used to pretreat inorganic fillers are as described above and are not described here again.

In one embodiment, with respect to 70 parts by weight of the vinyl-containing resin, the inorganic filler may comprise 10 parts by weight to 50 parts by weight of an inorganic filler other than the spherical silica or 10 parts by weight to 30 parts by weight of the inorganic filler other than the spherical silica, but the present invention is not limited thereto. In one embodiment, with respect to 70 parts by weight of the vinyl-containing resin, the inorganic filler may comprise 10 parts by weight to 30 parts by weight of the boron nitride.

In one embodiment, the resin composition may selectively further comprise an initiator, such as a peroxide and a carbon-carbon initiator that can generate free radicals. For example, the peroxide comprises, but not limited to, diisopropylbenzene peroxide (DCP), tert-butyl peroxybenzoate, dibenzoyl peroxide (BPO), 2,5-dimethyl-2,5-di(tert-butylperoxy)-3-hexyne (25B), bis(tert-butylperoxyisopropyl)benzene or a combination thereof. For example, with respect to 70 parts by weight of the vinyl-containing resin, the amount of the peroxide used in the present invention is not particularly limited, and may be 0.01 parts by weight to 1.0 part by weight, 0.05 parts by weight to 0.5 parts by weight, 0.05 parts by weight to 0.1 parts by weight, 0.02 parts by weight to 0.08 parts by weight, 0.15 parts by weight to 0.5 parts by weight, 0.1 parts by weight to 0.2 parts by weight, 0.4 parts by weight to 0.8 parts by weight, or 0.45 parts by weight to 0.67 parts by weight. For example, the carbon-carbon initiator comprises, but is not limited to, 2,3-dimethyl-2,3-diphenylbutane. In one embodiment, with respect to 70 parts by weight of the vinyl-containing resin, the resin composition may further comprise 1 part by weight to 20 parts by weight of the 2,3-dimethyl-2,3-diphenylbutane, but the present invention is not limited thereto.

In one embodiment, the resin composition may selectively further comprise an inhibitor. The inhibitor may comprise various molecular polymerization inhibitors or free-radical stabilized polymerization inhibitors known in the art. The molecular polymerization inhibitors may include, but are not limited to, phenolic compounds, quinone compounds, aromatic amine compounds, aromatic hydrocarbon nitro compounds, sulfur-containing compounds, variable-valent metal chlorides or a combination thereof. More specifically, the molecular polymerization inhibitors may comprise, but are not limited to phenol, hydroquinone, 4-tert-butylcatechol, benzoquinone, chloranil, 1,4-naphthoquinone, trimethylquinone, aniline, nitrobenzene, Na₂S, FeCl₃, CuCl₂ or a combination thereof. The free-radical stabilized polymerization inhibitors may include, but are not limited to, 1,1-diphenyl-2-trinitrophenylhydrazine (DPPH), triphenylmethyl free radical, 2,2,6,6-tetramethyl piperidine-1-oxide, derivatives of 2,2,6,6-tetramethylpiperidine-1-oxide or a combination thereof.

In one embodiment, the content of the inhibitor is not particularly limited. In another embodiment, with respect to 70 parts by weight of the vinyl-containing resin, the resin composition may further comprise 0.01 parts by weight to 0.5 parts by weight of the inhibitor, for example, may comprise 0.02 parts by weight, 0.05 parts by weight, 0.2 parts by weight, 0.3 parts by weight, 0.45 parts by weight or 0.5 parts by weight of the inhibitor, but the present invention is not limited thereto, and the content of the inhibitor can be adjusted according to the needs. In further another embodiment, the resin composition may not comprise an inhibitor, and that is, the content of the inhibitor is 0 parts by weight, which means that the inhibitor is not intentionally added into the resin composition.

In one embodiment, the resin composition may selectively further comprise a flame retardant. The flame retardant comprises, but is not limited to phosphorus-containing flame retardant. For example, the phosphorus-containing flame retardant may comprise ammonium polyphosphate, hydroquinone bis(diphenyl phosphate), bisphenol A bis(diphenylphosphate), tri (2-carboxyethyl)phosphine (TCEP), tris(chloroisopropyl) phosphate, trimethyl phosphate (TMP), dimethyl methyl phosphonate (DMMP), resorcinol bis(dixylenyl phosphate), RDXP (such as commercially available products PX-200, PX-201, PX-202), phosphazene (such as commercially available products SPB-100, SPH-100, SPV-100), melamine polyphosphate, 9,10-dihydro-9-oxa-10-phosphaphenanthrene-10-oxide (DOPO) and derivatives thereof (for example, di-DOPO compound) or resin thereof (for example, DOPO-HQ, DOPO-NQ, DOPO-PN, DOPO-BPN), DOPO-bonding epoxy resin, diphenylphosphine oxide (DPPO) or derivatives thereof (for example, di-DPPO compound) or resin thereof, melamine cyanurate, tri-hydroxyethyl isocyanurate or aluminum phosphinate (for example, commercially available products OP-930, OP-935). Herein, DOPO-PN is DOPO phenol novolak resin, DOPO-BPN may be DOPO bisphenol novolac resin such as DOPO-BPAN (DOPO-bisphenol A novolac), DOPO-BPFN (DOPO-bisphenol F novolac) or DOPO-BPSN (DOPO-bisphenol S novolac).

In one embodiment, when the resin composition comprises a flame retardant, with respect to 70 parts by weight of the vinyl-containing resin, the content of the flame retardant may be 30 parts by weight to 90 parts by weight, for example, 30 parts by weight, 40 parts by weight, 50 parts by weight, 60 parts by weight, 70 parts by weight, 80 parts by weight or 90 parts by weight. However, the present invention is not limited thereto, and the content of the flame retardant can be adjusted according to the needs. In another embodiment, the resin composition may not comprise the flame retardant, and that is, the content of the flame retardant is 0 parts by weight, which means that the flame retardant is not intentionally added into the resin composition.

In one embodiment, the resin composition may selectively further comprise a colorant, a toughening agent, a core-shell rubber or a combination thereof. The colorant of the present invention may include but is not limited to a dye or a pigment. The main function of the toughening agent is to improve the toughness of the resin composition. The toughening agent of the present invention may include but is not limited to carboxyl-terminated butadiene acrylonitrile rubber (CTBN) and other rubbers. The core-shell rubber of the present invention may include various commercially available core-shell rubbers.

In one embodiment, the content of the colorant, the toughening agent or the core-shell rubber may respectively be 0.01 parts by weight to 10 parts by weight with respect to 70 parts by weight of the vinyl-containing resin. For example, the content of the colorant, the toughening agent or the core-shell rubber may respectively be 0.01 parts by weight to 3 parts by weight or 0.05 parts by weight to 1 part by weight. However, the present invention is not limited thereto, and the contents of the aforesaid components can be adjusted according to the needs.

In one embodiment, the resin composition may selectively further comprise a silane coupling agent. For example, the silane coupling agent may comprise silane compounds (such as but not limited to siloxane), which can be further classified into amino silane compounds, epoxide silane compounds, vinyl silane compounds, hydroxy silane compounds and isocyanate silane compounds according to the functional groups. The content of the silane coupling agent is not particularly limited and can be adjusted according to the needs.

In one embodiment, the resin composition may selectively further comprise a solvent. The main function of the solvent is to dissolve the components in the resin composition, change the solid content of the resin composition, and adjust the viscosity of the resin composition. For example, the solvent may include but is not limited to methanol, ethanol, ethylene glycol monomethyl ether, acetone, butanone (also known as methyl ethyl ketone), methyl isobutyl ketone, cyclohexanone, toluene, xylene, methoxyethyl acetate, ethoxyethyl acetate, propoxyethyl acetate, ethyl acetate, propylene glycol methyl ether, dimethylformamide, dimethylacetamide, nitrogen methyl pyrrolidone or a mixed solvent thereof.

In one embodiment, the amount of the solvent added is not particularly limited, and can be adjusted according to the required viscosity of the resin composition. If a solvent is added to the resin composition, the solvent will be volatilized and removed when the resin composition is heated at high temperature to form a semi-cured state, so there is no solvent in the prepreg or the resin film, or only a trace amount of solvent is present in the prepreg or the resin film.

In one embodiment, the resin composition may further comprise 20 parts by weight to 70 parts by weight of methylcyclohexane. In one embodiment, 20 parts by weight to 70 parts by weight of methylcyclohexane is added into the resin composition of the present invention, which can make the copper-free laminate subsequently prepared from the resin composition have no long bubble striation.

The resin composition of one embodiment of the present invention can be made into various articles by various processing methods, including but not limited to a prepreg, a resin film, a laminate or a printed circuit board.

For example, the resin composition provided by one embodiment the present invention can be used to prepare a prepreg, which may include a reinforcing material and a layered structure disposed thereon. The layered structure may be formed by heating the aforementioned resin composition to a high temperature to form a semi-cured state (B-stage). The baking temperature for preparing the prepreg may be between 120° C. and 180° C., and preferably between 130° C. and 150° C. The baking time may be 3 minutes to 6 minutes. The reinforcing material may be any one of fiber material, woven fabric, and non-woven mats, and the woven fabric preferably includes glass fiber fabric. The type of the glass fiber fabric is not particularly limited, and can be various commercially available glass fiber fabrics that can be used for printed circuit boards, such as E-type glass fiber fabric, D-type glass fiber fabric, S-type glass fiber fabric, T-type glass fiber fabric, L-type glass fiber fabric or Q-type quartz fiber fabric, wherein the types of fibers may include yarn or roving, and the form may include spread form or standard form. The non-woven mats preferably include liquid crystal resin non-woven mats or quartz non-woven mats. The liquid crystal resin non-woven mats may be, for example, polyester non-woven mats, polyurethane non-woven mats, etc., and is not limited thereto. The woven fabric may also include liquid crystal resin woven fabric, such as polyester woven fabric or polyurethane woven fabric, and is not limited thereto. The reinforcing material can increase the mechanical strength of the prepreg. In one preferred embodiment, the reinforcing material may also be selectively pretreated with a siloxane compound. After the prepreg is subsequently heated for curing (C-stage), an insulating layer can be formed.

For example, the resin composition of one embodiment of the present invention may be made into a resin film, which is obtained by heating and baking to semi-cure the resin composition. The resin composition may be selectively applied on a polyethylene terephthalate film (PET film), a polyimide film (PI film), a copper foil or a resin-coated copper foil, followed by heating and baking to semi-cure the resin composition, and the resin composition is formed into a resin film.

For example, the resin composition of one embodiment of the present invention can be made into a laminate. For example, the laminate may include at least two metal foils and at least one insulating layer, and the insulating layer is disposed between the two metal foils. The insulating layer may be formed by laminating and curing the aforementioned resin composition at high temperature and under high pressure (C-stage). The suitable curing temperature may be, for example, between 200° C. and 240° C., and preferably between 210° C. and 230° C.; the curing time may be 120 minutes to 200 minutes, and preferably 140 minutes to 180 minutes; and the suitable pressure may be 400 psi to 600 psi, and preferably 450 psi to 550 psi. In one embodiment, the insulating layer may be obtained by curing at least one prepreg or at least one resin film. The metal foil can be made of copper, aluminum, nickel, platinum, silver, gold or alloys thereof. For example, the metal foil may be a copper foil. In a preferred embodiment, the laminate is a copper-clad laminate.

For example, the metal foil used in the laminate may be a hyper very low profile (HVLP) copper foil or a hyper very low profile 3 (HVLP3) copper foil. Herein, the roughness Rz of the matte side of the HVLP copper foil is less than or equal to 2 (micrometers) (Rz≤2 (μm)), and the roughness Rz of the matte side of the HVLP3 copper foil is less than or equal to 1 (micrometer) (Rz≤1 (μm)). The definition of roughness Rz is the same as the general definition in the field of copper foil technology, so it will not be repeated here.

For example, in one embodiment, the aforementioned laminate can be further processed into a printed circuit board after circuit processing, and the manufacturing method of the printed circuit board can be any known manufacturing method.

For example, the article manufactured by the resin composition provided by one embodiment of the present invention has at least one of the following characteristics:
the dissipation factor measured at a frequency of 10 GHz according to the method described in JIS C2565 is less than or equal to 0.0010, and for example, the dissipation factor ranges from 0.00089 to 0.00099;
the copper foil peel strength measured by the method described in IPC-TM-650 2.4.8 is greater than 3.0 lbs/inch, and for example, the copper foil peel strength ranges from 3.0 lbs/inch to 3.5 lbs/inch;
T288 heat resistance measured according to IPC-TM-650 2.4.24.1 is greater than or equal to 130 minutes, and for example, T288 heat resistance ranges from 130 minutes to 135 minutes;
T320 heat resistance measured according to the method described in IPC-TM-650 2.4.24.1 is greater than or equal to 60 minutes, and for example, T320 heat resistance ranges from 60 minutes to 65 minutes;
the copper-containing laminate is not exploded under the solder dipping heat resistance test according to the method described in IPC-TM-650 2.4.23;
the heat resistance test on the multilayer laminate is performed according to the method described in IPC-TM-650 2.4.13.1, and the number of times without the board explosion is more than 20 times, and for example, the heat resistance test of the multilayer laminate shows 20 to 25 times without board explosion, or for example, the heat resistance test of the multilayer laminate shows 20 to 21 times without board explosion;
a percent of thermal expansion at Z-axis is less than or equal to 2.0% measured according to a method described in IPC-TM-650 2.4.24.5, and for example, the percent of thermal expansion at Z-axis is between 1.7% and 2.0%; and
the moisture absorption is less than or equal to 0.13% after 3 hours of moisture absorption by pressure cooking test (PCT) according to the method described in IPC-TM-650 2.6.16.1, and for example, the moisture absorption ranges from 0.10% to 0.13%.

The chemical materials used in the following Embodiments and Comparative embodiments of the present invention are as follows.
SA9000: methacrylate-containing polyphenylene ether resin, commercially available
OPE-2st 2200: vinylbenzyl biphenyl-containing polyphenylene ether resin, commercially available.
OPE-2st 1200: vinylbenzyl biphenyl-containing polyphenylene ether resin, commercially available.

Compound represented by Formula (1): a compound represented by Formula (1-1-1) with a weight average molecular weight ranging from 1,000 to 5,000, commercially available.

Compound represented by Formula (2): a compound represented by Formula (2-1-2) with a weight average molecular weight ranging from 1,000 to 5,000, commercially available.

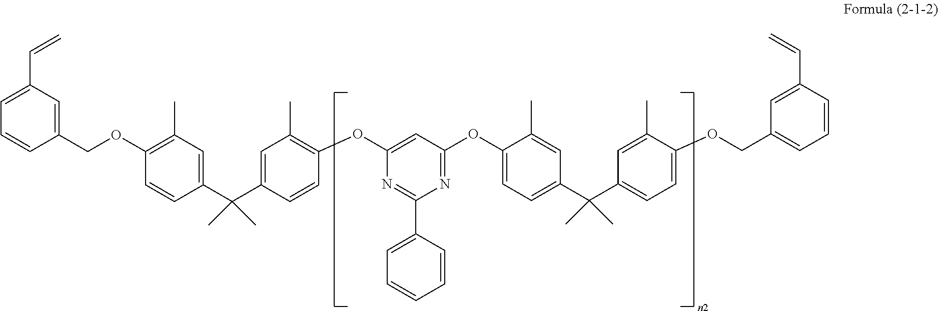

Compound represented by Formula (3): a mixture of a compound represented by Formula (3-1-2) and a compound represented by Formula (3-2-2), wherein a total amount of the compound represented by Formula (3-1-2) and the compound represented by Formula (3-2-2) is 100%, and a weight average molecular weight of the compound represented by Formula (3) ranges from 1,000 to 5,000, commercially available.

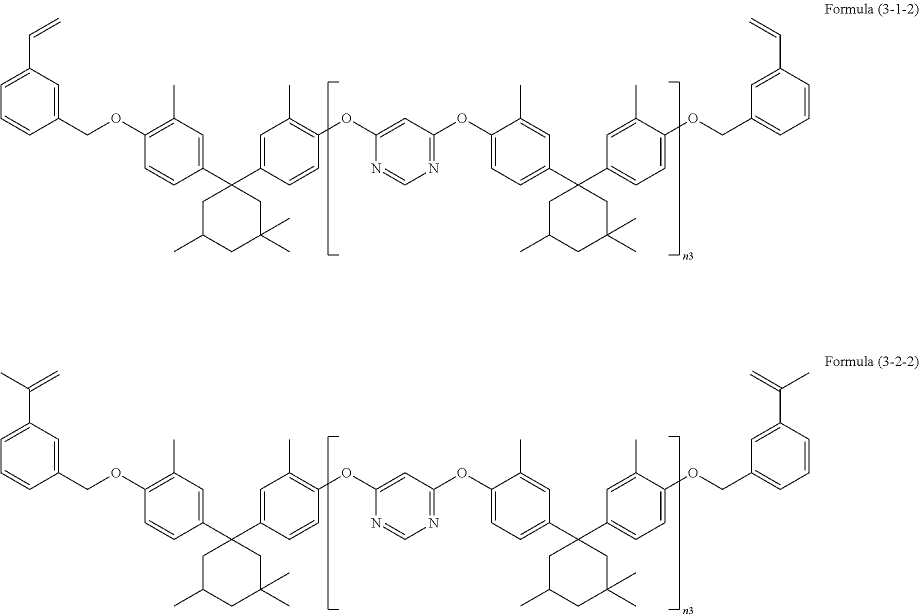

Compound represented by Formula (4): a compound represented by Formula (4-2) with a weight average molecular weight ranging from 1,000 to 5,000, commercially available.

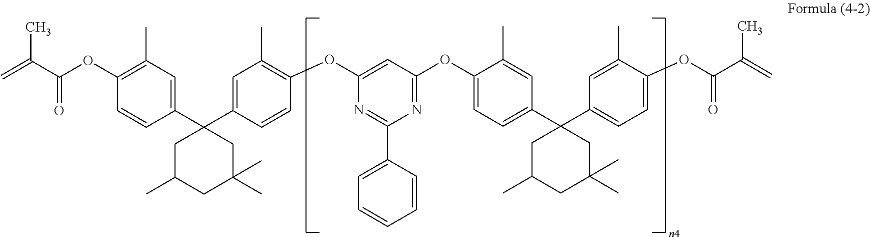

Compound represented by Formula (5): a mixture of a compound represented by Formula (5-1) and a compound represented by Formula (5-2), wherein a total amount of the compound represented by Formula (5-1) and the compound represented by Formula (5-2) is 100%, and a weight average molecular weight of the compound represented by Formula (5) ranges from 1,000 to 5,000, commercially available.

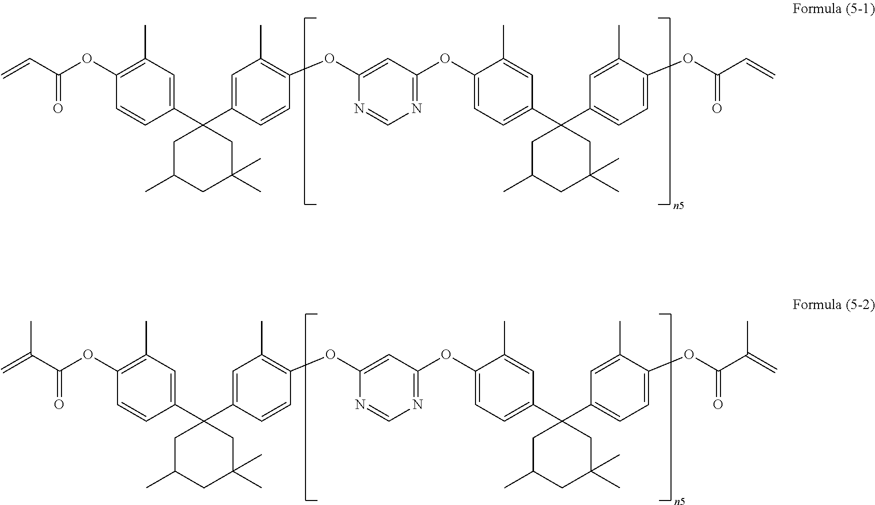

Compound represented by Formula (6): weight average molecular weight ranging from 1,000 to 5,000, commercially available.

X-3012P: ethylene-propylene-diene polymer (EPDM), purchased from Mitsui Chemicals.

Royalene 505: ethylene-propylene-diene polymer (EPDM), purchased from Lion Elastomers.

5013: cyclic olefin copolymer, purchased from TOPAS corporation.

Compound represented by Formula (7): z is an average number of repeating units based on number average molecular weight, and is a value from 1 to 20.

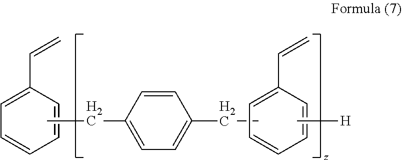

Divinylbenzene-styrene-ethylene terpolymer: a terpolymer of divinylbenzene, styrene and ethylene, wherein, in the polymerization raw materials of the divinylbenzene-styrene-ethylene terpolymer, the amount of ethylene is 70 mol % to 80 mol %, the amount of styrene is 20 mol % to 30 mol %, the amount of divinylbenzene is 0.01 mol % to 1 mol %, and a total amount of divinylbenzene, styrene and ethylene is 100 mol %, wherein a number average molecular weight of the divinylbenzene-styrene-ethylene terpolymer ranges from 5,000 to 15,000, commercially available.

Divinylbenzene-styrene-ethyl styrene terpolymer: purchased from Nippon Steel Corporation.

Ricon 257: divinylbenzene-styrene-butadiene terpolymer, purchased from Cray Valley.

Ricon 100: butadiene-styrene copolymer, purchased from Cray Valley.

Ricon 184MA6: butadiene-styrene copolymer adducted with maleic anhydride, purchased from Cray Valley.

Ricon 130: polybutadiene, purchased from Cray Valley.

BI-3040: hydrogenated polybutadiene, purchased from Nippon Soda.

H1051: hydrogenated styrene-butadiene-styrene triblock copolymer, commercially available.

G1726: hydrogenated styrene-butadiene-styrene triblock copolymer, commercially available.

TAIC: triallyl isocyanurate, commercially available.

DVBP: divinylbiphenyl, commercially available.

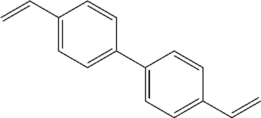 [SMILES: C=Cc1ccc(-c2ccc(C=C)cc2)cc1]

DAIP: diallyl isophthalate, commercially available.

25B: 2,5-dimethyl-2,5-di(tert-butylperoxy)-3-hexyne, commercially available.

DCP: diisopropylbenzene peroxide, commercially available.

SC2050 SMJ: spherical silica, commercially available.

SC2050 SVJ: spherical silica, commercially available.

Butanone (MEK) and toluene: commercially available.

Methylcyclohexane (MCH): commercially available.

BMI-70:3,3′-dimethyl-5,5′-diethyl-4,4′-diphenylmethane bismaleimide, commercially available.

BMI-80: bisphenol A diphenyl ether bismaleimide, commercially available.

MIR-3000: biphenyl-containing maleimide resin, purchased from Nippon Kayaku Co., Ltd.

MIR-5000: xylok-containing maleimide resin, purchased from Nippon Kayaku Co., Ltd.

X9-470: indane-containing maleimide resin, purchased from DIC corporation.

SLK-3000: maleimide containing C10-50 aliphatic structure, purchased from Shin-etsu chemical co., Ltd.

The various raw materials mentioned above were respectively prepared according to the amounts in Tables 1 to 7 below to prepare the resin compositions of Embodiments and Comparative embodiments of the present invention, and further prepared into various test samples. The unit of the amount of each component added in the resin composition in each Embodiments and Comparative embodiments is parts by weight, which refers to the parts by weight when the solid content of each component is 100%.

TABLE 1
The components of the resin composition of Embodiments
E1 to E5 (unit: parts by weight)

| Material | Component | Name | E1 | E2 | E3 | E4 | E5 |
|---|---|---|---|---|---|---|---|
| Vinyl- | Methacrylate- | SA9000 | 70 | 70 | 60 | 70 | 70 |
| containing | containing | | | | | | |
| polyphenylene | polyphenylene ether | | | | | | |
| ether | Vinylbenzyl biphenyl- | OPE-2st 2200 | | | | | |
| resin | containing | OPE-2st 1200 | | | 10 | | |
| | polyphenylene ether | | | | | | |
| Polymer A | Compound represented by | | 30 | 30 | 40 | 15 | 45 |
| | Formula (1-1-1) | | | | | | |
| | Compound represented by | | | | | | |
| | Formula (2-1-2) | | | | | | |
| | Mixture comprising compounds | | | | | | |
| | represented by Formula (3-1-2) | | | | | | |
| | and (3-2-2) | | | | | | |
| | Compound represented by | | | | | | |
| | Formula (4-2) | | | | | | |
| | Mixture comprising compounds | | | | | | |
| | represented by Formula | | | | | | |
| | (5-1) and (5-2) | | | | | | |
| | Compound represented | | | | | | |
| | by Formula (6) | | | | | | |
| Copolymer | EPDM 1 | X-3012P | | | | | |
| | EPDM 2 | Royalene 505 | | | | | |
| | Cyclic olefin | 5013 | | | | | |
| | Compound represented by Formula (7) | | | | | | |
| Divinylbenzene | Divinylbenzene-styrene-ethylene | | 40 | 20 | 55 | 40 | 40 |
| polymer | terpolymer | | | | | | |
| | Divinylbenzene-styrene-ethyl styrene | | | | | | |
| | terpolymer | | | | | | |
| | Divinylbenzene- | Ricon 257 | | | | | |
| | styrene-butadiene | | | | | | |
| | terpolymer | | | | | | |
| Vinyl- | Butadiene-styrene | Ricon 100 | | | | | |
| containing | copolymer | Ricon | | | | | |
| polyolefin | | 184MA6 | | | | | |
| | Polybutadiene | Ricon 130 | | | | | |
| Hydrogenated | Hydrogenated | BI-3040 | | | | | |
| polyolefin | polybutadiene | | | | | | |
| | Hydrogenated styrene- | H1051 | 20 | 20 | 20 | 20 | 20 |
| | butadiene-styrene | G1726 | | | | | |
| | triblock copolymer | | | | | | |
| Additive 1 | Triallyl isocyanurate | TAIC | | | | | |
| | Divinylbiphenyl | DVBP | | | | | |
| | Diallyl isophthalate | DAIP | | | | | |
| Initiator | Peroxide | 25B | 0.48 | 0.48 | 0.48 | 0.55 | 0.35 |
| | | DCP | 0.12 | 0.12 | 0.12 | 0.03 | 0.25 |
| Filler | Spherical silica | SC2050 SMJ | 240 | 240 | 240 | 240 | 130 |
| | | SC2050 SVJ | | | | | |
| Solvent | MEK | | 80 | 80 | 80 | 80 | 80 |
| | Toluene | | 200 | 200 | 200 | 200 | 200 |
| Additive 2 | Methylcyclohexane | | 40 | 40 | 40 | 40 | 40 |
| Characteristics | Test conditions | Unit | E1 | E2 | E3 | E4 | E5 |
| Df | 10 GHz | — | 0.00096 | 0.00099 | 0.00094 | 0.00095 | 0.00097 |
| P/S | Using HVLP3(Hoz) | lbs/inch | 3.35 | 3.27 | 3.38 | 3.25 | 3.38 |
| | copper foil | | | | | | |
| Heat | T288 | Minutes | >130 | >130 | >130 | >130 | >130 |
| resistance | T320 | Minutes | >60 | >60 | >60 | >60 | >60 |
| | S/D | — | OK | OK | OK | OK | OK |
| Reliability | Heat resistance of eight- | Number of | >20 | >20 | >20 | >20 | >20 |
| | layer laminate | times | | | | | |
| Percent of | Percent of thermal | % | 1.85 | 1.77 | 1.89 | 1.93 | 1.79 |
| thermal | expansion at Z-axis | | | | | | |
| expansion | measured by TMA | | | | | | |
| Moisture | PCT, 3 hours | % | 0.115 | 0.108 | 0.113 | 0.121 | 0.126 |
| absorption | | | | | | | |
| Long | Striation >12 mil | Number of | 0 | 0 | 0 | 0 | 0 |
| bubble | | striations | | | | | |
| striation | Striation = 5~12 mil | Number of | 0 | 0 | 0 | 0 | 0 |
| | | striations | | | | | |

TABLE 2
The components of the resin composition of Embodiments
E6 to E10 (unit: parts by weight)

| Material | Component | Name | E6 | E7 | E8 | E9 | E10 |
|---|---|---|---|---|---|---|---|
| Vinyl- | Methacrylate- | SA9000 | 50 | 62 | 55 | 70 | 70 |
| containing | containing | | | | | | |
| polyphenylene | polyphenylene ether | | | | | | |
| ether | Vinylbenzyl biphenyl- | OPE-2st 2200 | 14 | 6 | 11 | | |
| resin | containing | OPE-2st 1200 | 6 | 2 | 4 | | |
| | polyphenylene ether | | | | | | |
| Polymer A | Compound represented by Formula | | 10 | 18 | 20 | 30 | 30 |
| | (1-1-1) | | | | | | |
| | Compound represented by Formula | | | 3 | 8 | | |
| | (2-1-2) | | | | | | |
| | Mixture comprising compounds | | | 11 | 2 | | |
| | represented by Formula (3-1-2) and | | | | | | |
| | (3-2-2) | | | | | | |
| | Compound represented by Formula | | | | | | |
| | (4-2) | | | | | | |
| | Mixture comprising compounds | | | | | | |
| | represented by Formula (5-1) and (5-2) | | | | | | |
| | Compound represented by Formula (6) | | | | | | |
| Copolymer | EPDM 1 | X-3012P | | | | | |
| | EPDM 2 | Royalene 505 | | | | | |
| | Cyclic olefin | 5013 | | | | | |
| | Compound represented by Formula (7) | | | | | | |
| Divinylbenzene | Divinylbenzene-styrene-ethylene | | 50 | 38 | 42 | 40 | 40 |
| polymer | terpolymer | | | | | | |
| | Divinylbenzene-styrene-ethyl styrene | | | | | | |
| | terpolymer | | | | | | |
| | Divinylbenzene- | Ricon 257 | | | | | |
| | styrene-butadiene | | | | | | |
| | terpolymer | | | | | | |
| Vinyl- | Butadiene-styrene | Ricon 100 | 2 | | | | |
| containing | copolymer | Ricon | 0.6 | 0.4 | 0.5 | | |
| polyolefin | | 184MA6 | | | | | |
| | Polybutadiene | Ricon 130 | | | 1 | | |
| Hydrogenated | Hydrogenated | BI-3040 | 15 | 1 | 1 | | |
| polyolefin | polybutadiene | | | | | | |
| | Hydrogenated styrene- | H1051 | | 2 | | 20 | 20 |
| | butadiene-styrene | G1726 | | 20 | 23 | | |
| | triblock copolymer | | | | | | |
| Additive 1 | Triallyl isocyanurate | TAIC | 3 | | 5 | | |
| | Divinylbiphenyl | DVBP | 2 | 3 | | | |
| | Diallyl isophthalate | DAIP | 3 | 2 | | | |
| Initiator | Peroxide | 25B | 0.55 | 0.42 | 0.45 | 0.48 | 0.48 |
| | | DCP | 0.12 | 0.13 | 0.12 | 0.12 | 0.12 |
| Filler | Spherical silica | SC2050 SMJ | 255 | 238 | 235 | 240 | 240 |
| | | SC2050 SVJ | 10 | 5 | 20 | | |
| Solvent | MEK | | 80 | 80 | 80 | 120 | 80 |
| | Toluene | | 220 | 170 | 200 | 200 | 240 |
| Additive 2 | Methylcyclohexane | | 20 | 70 | 40 | 0 | 0 |
| Characteristics | Test conditions | Unit | E6 | E7 | E8 | E9 | E10 |
| Df | 10 GHz | — | 0.00091 | 0.00092 | 0.00089 | 0.00098 | 0.00098 |
| P/S | Using HVLP3(Hoz) | lbs/inch | 3.38 | 3.41 | 3.46 | 3.32 | 3.29 |
| | copper foil | | | | | | |
| Heat | T288 | Minutes | >130 | >130 | >130 | >130 | >130 |
| resistance | T320 | Minutes | >60 | >60 | >60 | >60 | >60 |
| | S/D | — | OK | OK | OK | OK | OK |
| Reliability | Heat resistance of eight- | Number of | >20 | >20 | >20 | >20 | >20 |
| | layer laminate | times | | | | | |
| Percent of | Percent of thermal | % | 1.96 | 1.81 | 1.76 | 1.86 | 1.88 |
| thermal | expansion at Z-axis | | | | | | |
| expansion | measured by TMA | | | | | | |
| Moisture | PCT, 3 hours | % | 0.115 | 0.112 | 0.109 | 0.127 | 0.123 |
| absorption | | | | | | | |
| Long | Striation >12 mil | Number of | 0 | 0 | 0 | 2 | 1 |
| bubble | | striations | | | | | |
| striation | Striation = 5~12 mil | Number of | 0 | 0 | 0 | 5 | 3 |
| | | striations | | | | | |

TABLE 3
The components of the resin composition of Embodiments
E11 to E13 (unit: parts by weight)

| Material | Component | Name | E11 | E12 | E13 |
|---|---|---|---|---|---|
| Vinyl-containing | Methacrylate-containing | SA9000 | 70 | 70 | 70 |
| polyphenylene | polyphenylene ether | | | | |
| ether resin | Vinylbenzyl biphenyl- | OPE-2st 2200 | | | |
| | containing | OPE-2st 1200 | | | |
| | polyphenylene ether | | | | |
| Polymer A | Compound represented by Formula | | 20 | 3 | 22 |
| | (1-1-1) | | | | |
| | Compound represented by Formula | | | | |
| | (2-1-2) | | | | |
| | Mixture comprising compounds | | | | |
| | represented by Formula (3-1-2) and | | | | |
| | (3-2-2) | | | | |
| | Compound represented by Formula | | 5 | | |
| | (4-2) | | | | |
| | Mixture comprising compounds | | 3 | | |
| | represented by Formula (5-1) and (5-2) | | | | |
| | Compound represented by Formula (6) | | 4 | | |
| Copolymer | EPDM 1 | X-3012P | | | |
| | EPDM 2 | Royalene 505 | | | |
| | Cyclic olefin | 5013 | | | |
| | Compound represented by Formula (7) | | | | |
| Divinylbenzene | Divinylbenzene-styrene-ethylene | | 40 | 45 | 5 |
| polymer | terpolymer | | | | |
| | Divinylbenzene-styrene-ethyl styrene | | | | |
| | terpolymer | | | | |
| | Divinylbenzene-styrene- | Ricon 257 | | | |
| | butadiene terpolymer | | | | |
| Vinyl-containing | Butadiene-styrene | Ricon 100 | | | |
| polyolefin | copolymer | Ricon 184MA6 | | | |
| | Polybutadiene | Ricon 130 | | | |
| Hydrogenated | Hydrogenated | BI-3040 | | | |
| polyolefin | polybutadiene | | | | |
| | Hydrogenated styrene- | H1051 | 20 | 25 | 38 |
| | butadiene-styrene | G1726 | | | |
| | triblock copolymer | | | | |
| Additive 1 | Triallyl isocyanurate | TAIC | | | |
| | Divinylbiphenyl | DVBP | | | |
| | Diallyl isophthalate | DAIP | | | |
| Initiator | Peroxide | 25B | 0.35 | 0.48 | 0.41 |
| | | DCP | 0.25 | 0.12 | 0.07 |
| Filler | Spherical silica | SC2050 SMJ | 130 | 252 | 240 |
| | | SC2050 SVJ | | | |

| | | | | |
|---|---|---|---|---|
| Solvent | MEK | 80 | 80 | 80 |
| | Toluene | 200 | 200 | 200 |
| Additive 2 | Methylcyclohexane | 40 | 40 | 40 |

| Characteristics | Test conditions | Unit | E11 | E12 | E13 |
|---|---|---|---|---|---|
| Df | 10 ghz | — | 0.00098 | 0.00092 | 0.00098 |
| P/S | Using HVLP3(Hoz) | lbs/inch | 3.36 | 3.27 | 3.38 |
| | copper foil | | | | |
| Heat resistance | T288 | Minutes | >130 | >130 | >130 |
| | T320 | Minutes | >60 | >60 | >60 |
| | S/D | — | OK | OK | OK |
| Reliability | Heat resistance of eight- | Number of | >20 | >20 | >20 |
| | layer laminate | times | | | |
| Percent of | Percent of thermal | % | 1.84 | 1.98 | 1.81 |
| thermal | expansion at Z-axis | | | | |
| expansion | measured by TMA | | | | |
| Moisture | PCT, 3 hours | % | 0.111 | 0.122 | 0.125 |
| absorption | | | | | |
| Long bubble | Striation > 12 mil | Number of | 0 | 0 | 0 |
| striation | | striations | | | |
| | Striation = 5~12 mil | Number of | 0 | 0 | 0 |
| | | striations | | | |

TABLE 4
The components of the resin composition of Embodiments
E14 to E16 (unit: parts by weight)

| Material | Component | Name | E14 | E15 | E16 |
|---|---|---|---|---|---|
| Maleimide | Aromatic maleimide | BMI-70 | | 2 | 2 |
| resin | | BMI-80 | 6 | | 2 |
| | | MIR-3000 | | 2 | 3 |
| | | MIR-5000 | 6 | | 3 |
| | | X9-470 | 36 | 48 | 36 |
| | Aliphatic maleimide | SLK-3000 | | | 5 |
| Vinyl- | Methacrylate-containing | SA9000 | 18 | | 15 |
| containing | polyphenylene ether | | | | |
| polyphenylene | | | | | |
| ether resin | | | | | |
| Vinyl- | Butadiene-styrene | Ricon 100 | 3 | 12 | 2 |
| containing | copolymer | Ricon 184MA6 | 1 | 1 | 1 |
| polyolefin | Polybutadiene | Ricon 130 | | 5 | 1 |
| Hydrogenated | Hydrogenated | BI-3040 | | | 1 |
| polyolefin | polybutadiene | | | | |
| | Hydrogenated styrene- | H1051 | 22 | 23 | 20 |
| | butadiene-styrene | G1726 | 5 | 3 | 5 |
| | triblock copolymer | | | | |
| Polymer A | Compound represented by Formula (1-1-1) | | 30 | 25 | 20 |
| | Compound represented by Formula (2-1-2) | | 2 | 10 | |
| | Mixture comprising compounds | | 2 | 10 | |
| | represented by Formula (3-1-2) and (3-2-2) | | | | |
| | Compound represented by Formula (4-2) | | | | |
| | Compound represented by Formula (6) | | | | |
| Divinylbenzene | Divinylbenzene-styrene-ethylene | | 30 | 20 | 38 |
| polymer | terpolymer | | | | |
| Initiator | Peroxide | 25B | 0.42 | 0.35 | 0.39 |
| | | DCP | 0.12 | 0.25 | 0.06 |
| Filler | Spherical silica | SC2050 SMJ | 235 | 240 | 248 |
| | | SC2050 SVJ | 10 | 13 | 12 |

| | | | | |
|---|---|---|---|---|
| Solvent | MEK | 80 | 80 | 80 |
| | Toluene | 180 | 200 | 170 |
| Additive | Methylcyclohexane | 60 | 40 | 70 |

| Characteristics | Test conditions | Unit | E14 | E15 | E16 |
|---|---|---|---|---|---|
| Df | 10 ghz | — | 0.00099 | 0.00099 | 0.00098 |
| P/S | Using HVLP3(Hoz) | lbs/inch | 3.31 | 3.22 | 3.29 |
| | copper foil | | | | |
| Heat resistance | T288 | Minutes | >130 | >130 | >130 |
| | T320 | Minutes | >60 | >60 | >60 |
| | S/D | — | OK | OK | OK |
| Reliability | Heat resistance of eight- | Number of | >20 | >20 | >20 |
| | layer laminate | times | | | |
| Percent of | Percent of thermal | % | 1.75 | 1.69 | 1.82 |
| thermal | expansion at Z-axis | | | | |
| expansion | measured by TMA | | | | |
| Moisture | PCT, 3 hours | % | 0.114 | 0.112 | 0.116 |
| absorption | | | | | |
| Long bubble | Striation > 12 mil | Number of | 0 | 0 | 0 |
| striation | | striations | | | |
| | Striation = 5~12 mil | Number of | 0 | 0 | 0 |
| | | striations | | | |

TABLE 5
The components of the resin composition of Embodiments
E17 to E19 (unit: parts by weight)

| Material | Component | Name | E17 | E18 | E19 |
|---|---|---|---|---|---|
| Maleimide | Aromatic maleimide | BMI-70 | 10 | 4 | 2 |
| resin | | BMI-80 | | | 3 |
| | | MIR-3000 | | | |
| | | MIR-5000 | | | 4 |
| | | X9-470 | 40 | 48 | 42 |
| | Aliphatic maleimide | SLK-3000 | | | |
| Vinyl- | Methacrylate-containing | SA9000 | 20 | | |
| containing | polyphenylene ether | | | | |
| polyphenylene | | | | | |
| ether resin | | | | | |
| Vinyl- | Butadiene-styrene | Ricon 100 | | 17 | 13 |
| containing | copolymer | Ricon 184MA6 | | 1 | 1 |
| polyolefin | Polybutadiene | Ricon 130 | | | 5 |
| Hydrogenated | Hydrogenated | BI-3040 | | | |
| polyolefin | polybutadiene | | | | |
| | Hydrogenated styrene- | H1051 | 25 | 6 | 5 |
| | butadiene-styrene | G1726 | | 25 | 25 |
| | triblock copolymer | | | | |
| Polymer A | Compound represented by Formula (1-1-1) | | 45 | 27 | 15 |
| | Compound represented by Formula (2-1-2) | | | 4 | |
| | Mixture comprising compounds | | | 4 | 15 |
| | represented by Formula (3-1-2) and (3-2-2) | | | | |
| | Compound represented by Formula (4-2) | | | | 5 |
| | Compound represented by Formula (6) | | | | 5 |
| Divinylbenzene | Divinylbenzene-styrene-ethylene | | 50 | 24 | 36 |
| polymer | terpolymer | | | | |
| Initiator | Peroxide | 25B | 0.41 | 0.43 | 0.42 |
| | | DCP | 0.25 | 0.12 | 0.12 |
| Filler | Spherical silica | SC2050 SMJ | 220 | 240 | 235 |
| | | SC2050 SVJ | 5 | 15 | 13 |

| | | | | |
|---|---|---|---|---|
| Solvent | MEK | 80 | 80 | 80 |
| | Toluene | 200 | 220 | 180 |
| Additive | Methylcyclohexane | 40 | 20 | 60 |

| Characteristics | Test conditions | Unit | E17 | E18 | E19 |
|---|---|---|---|---|---|
| Df | 10 ghz | — | 0.00097 | 0.00099 | 0.00098 |
| P/S | Using HVLP3(Hoz) | lbs/inch | 3.34 | 3.21 | 3.25 |
| | copper foil | | | | |
| Heat resistance | T288 | Minutes | >130 | >130 | >130 |
| | T320 | Minutes | >60 | >60 | >60 |
| | S/D | — | OK | OK | OK |
| Reliability | Heat resistance of eight- | Number of | >20 | >20 | >20 |
| | layer laminate | times | | | |
| Percent of | Percent of thermal | % | 1.95 | 1.88 | 1.86 |
| thermal | expansion at Z-axis | | | | |
| expansion | measured by TMA | | | | |
| Moisture | PCT, 3 hours | % | 0.113 | 0.118 | 0.122 |
| absorption | | | | | |
| Long bubble | Striation > 12 mil | Number of | 0 | 0 | 0 |
| striation | | striations | | | |
| | Striation = 5~12 mil | Number of | 0 | 0 | 0 |
| | | striations | | | |

TABLE 6
The components of the resin composition of Comparative
embodiments C1 to C5 (unit: parts by weight)

| Material | Component | Name | C1 | C2 | C3 | C4 | C5 |
|---|---|---|---|---|---|---|---|
| Vinyl- | Methacrylate- | SA9000 | 70 | 70 | 70 | 70 | 70 |
| containing | containing | | | | | | |
| polyphenylene | polyphenylene ether | | | | | | |
| ether | Vinylbenzyl biphenyl- | OPE-2st 2200 | | | | | |
| resin | containing | OPE-2st 1200 | | | | | |
| | polyphenylene ether | | | | | | |
| Polymer A | Compound represented by Formula | | | | | | 30 |
| | (1-1-1) | | | | | | |
| | Compound represented by Formula | | | | | | |
| | (2-1-2) | | | | | | |
| | Mixture comprising compounds | | | | | | |
| | represented by Formula (3-1-2) and | | | | | | |
| | (3-2-2) | | | | | | |
| | Compound represented by Formula | | | | | | |
| | (4-2) | | | | | | |
| | Mixture comprising compounds | | | | | | |
| | represented by Formula (5-1) and (5-2) | | | | | | |
| | Compound represented by Formula (6) | | | | | | |
| Copolymer | EPDM 1 | X-3012P | 30 | | | | |
| | EPDM 2 | Royalene 505 | | 30 | | | |
| | Cyclic olefin | 5013 | | | 30 | | |
| | Compound represented by Formula (7) | | | | | 30 | |
| Divinylbenzene | Divinylbenzene-styrene-ethylene | | 40 | 40 | 40 | 40 | |
| polymer | terpolymer | | | | | | |
| | Divinylbenzene-styrene-ethyl styrene | | | | | | |
| | terpolymer | | | | | | |
| | Divinylbenzene- | Ricon 257 | | | | | 40 |
| | styrene-butadiene | | | | | | |
| | terpolymer | | | | | | |
| Vinyl- | Butadiene-styrene | Ricon 100 | | | | | |
| containing | copolymer | Ricon 184MA6 | | | | | |
| polyolefin | Polybutadiene | Ricon 130 | | | | | |
| Hydrogenated | Hydrogenated | BI-3040 | | | | | |
| | polybutadiene | | | | | | |
| polyolefin | Hydrogenated styrene- | H1051 | 20 | 20 | 20 | 20 | 20 |
| | butadiene-styrene | | | | | | |
| | triblock copolymer | G1726 | | | | | |
| Additive 1 | Triallyl isocyanurate | TAIC | | | | | |
| | Divinylbiphenyl | DVBP | | | | | |
| | Diallyl isophthalate | DAIP | | | | | |
| Initiator | Peroxide | 25B | 0.48 | 0.48 | 0.48 | 0.48 | 0.48 |
| | | DCP | 0.12 | 0.12 | 0.12 | 0.12 | 0.12 |
| Filler | Spherical silica | SC2050 SMJ | 240 | 240 | 240 | 240 | 240 |
| | | SC2050 SVJ | | | | | |
| Solvent | MEK | | 80 | 80 | 80 | 80 | 80 |
| | Toluene | | 200 | 200 | 200 | 200 | 200 |
| Additive 2 | Methylcyclohexane | | 40 | 40 | 40 | 40 | 40 |
| Characteristics | Test conditions | Unit | C1 | C2 | C3 | C4 | C5 |
| Df | 10 ghz | — | 0.00105 | 0.00106 | 0.00111 | 0.00094 | 0.00115 |
| P/S | Using HVLP3(Hoz) | lbs/inch | 2.55 | 2.61 | 2.72 | 2.66 | 2.73 |
| | copper foil | | | | | | |
| Heat | T288 | Minutes | 48 | 52 | 65 | >130 | >130 |
| resistance | T320 | Minutes | 8 | 10 | 12 | 45 | 48 |
| | S/D | — | NG | NG | NG | NG | OK |
| Reliability | Heat resistance of | Number | Board | Board | Board | Board | Board |
| | eight-layer laminate | of times | exploded | exploded | exploded | exploded | exploded |
| | | | in 2 | in 5 | in 7 | in 10 | in 16 |
| | | | times | times | times | times | times |
| Percent of | Percent of thermal | % | 2.36 | 2.43 | 2.28 | 2.05 | 2.27 |
| thermal | expansion at Z-axis | | | | | | |
| expansion | measured by TMA | | | | | | |
| Moisture | PCT, 3 hours | % | 0.121 | 0.126 | 0.117 | 0.119 | 0.137 |
| absorption | | | | | | | |
| Long | Striation >12 mil | Number of | 0 | 0 | 0 | 0 | 0 |
| bubble | | striations | | | | | |
| striation | Striation = 5~12 mil | Number of | 0 | 0 | 0 | 0 | 0 |
| | | striations | | | | | |

TABLE 7
The components of the resin composition of Comparative
embodiments C6 to C10 (unit: parts by weight)

| Material | Component | Name | C6 | C7 | C8 | C9 | C10 |
|---|---|---|---|---|---|---|---|
| Vinyl- | Methacrylate- | SA9000 | 70 | 70 | 70 | 60 | 70 |
| containing | containing | | | | | | |
| polyphenylene | polyphenylene ether | | | | | | |
| ether | Vinylbenzyl | OPE-2st 2200 | | | | | |
| resin | biphenyl-containing | OPE-2st 1200 | | | | 10 | |
| | polyphenylene ether | | | | | | |
| Polymer A | Compound represented by Formula | | 30 | 70 | | | 45 |
| | (1-1-1) | | | | | | |
| | Compound represented by Formula | | | | | | |
| | (2-1-2) | | | | | | |
| | Mixture comprising compounds | | | | | | |
| | represented by Formula (3-1-2) and | | | | | | |
| | (3-2-2) | | | | | | |
| | Compound represented by Formula | | | | | | |
| | (4-2) | | | | | | |
| | Mixture comprising compounds | | | | | | |
| | represented by Formula (5-1) and (5-2) | | | | | | |
| | Compound represented by Formula (6) | | | | | | |
| Copolymer | EPDM 1 | X-3012P | | | | 10 | |
| | EPDM 2 | Royalene 505 | | | | 5 | |
| | Cyclic olefin | 5013 | | | | 5 | |
| | Compound represented by Formula (7) | | | | | 20 | |
| Divinylbenzene | Divinylbenzene-styrene-ethylene | | | | 70 | 55 | |
| polymer | terpolymer | | | | | | |
| | Divinylbenzene-styrene-ethyl styrene | | 40 | | | | 20 |
| | terpolymer | | | | | | |
| | Divinylbenzene- | Ricon 257 | | | | | 20 |
| | styrene-butadiene | | | | | | |
| | terpolymer | | | | | | |
| Vinyl- | Butadiene-styrene | Ricon 100 | | | | | |
| containing | copolymer | Ricon 184MA6 | | | | | |
| polyolefin | Polybutadiene | Ricon 130 | | | | | |
| Hydrogenated | Hydrogenated | BI-3040 | | | | | |
| polyolefin | polybutadiene | | | | | | |
| | Hydrogenated styrene- | H1051 | 20 | 20 | 20 | 20 | 20 |
| | butadiene-styrene | G1726 | | | | | |
| | triblock copolymer | | | | | | |
| Additive 1 | Triallyl isocyanurate | TAIC | | | | | |
| | Divinylbiphenyl | DVBP | | | | | |
| | Diallyl isophthalate | DAIP | | | | | |
| Initiator | Peroxide | 25B | 0.48 | 0.48 | 0.48 | 0.48 | 0.48 |
| | | DCP | 0.12 | 0.12 | 0.12 | 0.12 | 0.12 |
| Filler | Spherical silica | SC2050 SMJ | 240 | 240 | 240 | 240 | 240 |
| | | SC2050 SVJ | | | | | |
| Solvent | MEK | | 80 | 80 | 80 | 120 | 80 |
| | Toluene | | 200 | 200 | 200 | 200 | 240 |
| Additive 2 | Methylcyclohexane | | 40 | 40 | 40 | 0 | 0 |
| Characteristics | Test conditions | Unit | C6 | C7 | C8 | C9 | C10 |
| Df | 10 ghz | — | 0.00102 | 0.00133 | 0.00092 | 0.00097 | 0.00106 |
| P/S | Using HVLP3(Hoz) | lbs/inch | 2.67 | 3.53 | 3.15 | 3.18 | 3.21 |
| | copper foil | | | | | | |
| Heat | T288 | Minutes | 103 | >130 | 115 | 35 | >130 |
| resistance | T320 | Minutes | 21 | 45 | 23 | 2 | 53 |
| | S/D | — | OK | OK | OK | NG | OK |
| Reliability | Heat resistance of | Number | Board | Board | Board | Board | Board |
| | eight-layer laminate | of times | exploded | exploded | exploded | exploded | exploded |
| | | | in 10 | in 17 | in 10 | in 2 | in 13 |
| | | | times | times | times | times | times |
| Percent of | Percent of thermal | % | 1.84 | 1.76 | 2.11 | 2.08 | 2.19 |
| thermal | expansion at Z-axis | | | | | | |
| expansion | measured by TMA | | | | | | |
| Moisture | PCT, 3 hours | % | 0.114 | 0.121 | 0.118 | 0.116 | 0.131 |
| absorption | | | | | | | |
| Long | Striation >12 mil | Number of | 0 | 0 | 0 | 13 | 0 |
| bubble | | striations | | | | | |
| striation | Striation = 5~12 mil | Number of | 0 | 0 | 0 | 45 | 0 |
| | | striations | | | | | |

### Varnish

According to the amounts shown Table 1 to Table 7, the components of each Embodiments (abbreviated as E, such as E1 to E19) and Comparative embodiments (abbreviated as C, such as C1 to C10) were respectively added into the stirring tank and stirred. After mixing uniformly, the obtained resin composition was called as a varnish.

The formulation method of the resin composition of Embodiment 1 (E1) is used as an example. 70 parts by weight of SA9000 and 20 parts by weight of H1051 were added into a stirrer containing 80 parts by weight of MEK, 40 parts by weight of methylcyclohexane and 200 parts by weight of toluene, followed by stirring until SA9000 and H1051 were completely dissolved and mixed evenly. Then, 30 parts by weight of the compound represented by Formula (1) and 40 parts by weight of divinylbenzene-styrene-ethylene terpolymer were added and stirred until they were mixed evenly. Then, 240 parts by weight of SC-2050 SMJ were added and stirred until they were mixed evenly, followed by adding 0.6 parts by weight of 25B and 0.12 parts by weight of DCP. The mixture was stirred until mixed evenly to obtain a varnish of the resin composition of Embodiment 1 (E1).

In addition, according to the amounts shown in Table 1 to Table 7, the varnishes of the resin compositions of Embodiments 2 to 19 (E2 to E19) and Comparative embodiments 1 to 10 (C1 to C10) were prepared with reference to the preparation method of the varnish of Embodiment 1 (E1).

With reference to the following methods, the varnishes of Embodiments 1 to 19 (E1 to E19) and Comparative embodiments 1 to 10 (C1 to C10) were used to prepare the samples (respectively including prepregs, copper-containing laminates and copper-free laminates) to be tested. Then, the characteristic analyses were performed according to the following conditions.

### Prepreg 1 (Using 1035 Q-Type Quartz Fiber Fabric)

The resin compositions in different Embodiments (E1 to E19) and Comparative embodiments (C1 to C10) listed in Table 1 to Table 7 were respectively put into an impregnation tank in batches. The quartz fiber fabric (such as 1035 Q-type quartz fiber fabric) was passed through the above impregnation tank, and the resin compositions were adhered to the quartz fiber fabric. After heating at 130° C. for 4 minutes, the resin compositions were turned into the semi-cured state (B-Stage) to obtain the prepreg 1 (the resin content is about 80%).

### Prepreg 2 (Using 2116 L-Glass Fiber Fabric)

The resin compositions in different Embodiments (E1 to E19) and Comparative embodiments (C1 to C10) listed in Table 1 to Table 7 were respectively put into an impregnation tank in batches. The glass fiber fabric (such as 2116 L-glass fiber fabric) was passed through the above impregnation tank, and the resin compositions were adhered to the glass fiber fabric. After heating at 130° C. for 4 minutes, the resin compositions were turned into the semi-cured state (B-Stage) to obtain the prepreg 2 (the resin content is about 53%).

### Prepreg 3 (Using 2116 E-Glass Fiber Fabric)

The resin compositions in different Embodiments (E1 to E19) and Comparative embodiments (C1 to C10) listed in Table 1 to Table 7 were respectively put into an impregnation tank in batches. The glass fiber fabric (such as 2116 E-glass fiber fabric) was passed through the above impregnation tank, and the resin compositions were adhered to the glass fiber fabric. After heating at 130° C. for 4 minutes, the resin compositions were turned into the semi-cured state (B-Stage) to obtain the prepreg 3 (the resin content is about 58%).

### Prepreg 4 (Using 1080 L-Glass Fiber Fabric)

The resin compositions in different Embodiments (E1 to E19) and Comparative embodiments (C1 to C10) listed in Table 1 to Table 7 were respectively put into an impregnation tank in batches. The glass fiber fabric (such as 1080 L-glass fiber fabric) was passed through the above impregnation tank, and the resin compositions were adhered to the glass fiber fabric. After heating at 130° C. for 4 minutes, the resin compositions were turned into the semi-cured state (B-Stage) to obtain the prepreg 4 (the resin content is about 70%).

Copper-Containing Laminate 1 (or Called as Copper-Clad Laminate 1, which was Prepared by Laminating Two Prepregs 1)

Two reverse treated copper foils (RTFs) with a thickness of 18 μm and the same two aforementioned prepregs 1 were provided. One reverse treated copper foil, two prepregs 1 and one reverse treated copper foil were laminated in sequence, and the lamination was performed under a vacuum condition at 500 psi and 220° C. for 150 minutes to obtain a copper-containing laminate 1, which was prepared by laminating two identical prepregs 1.

### Copper-Free Laminate 1

The aforesaid copper-containing laminate 1 was etched to remove the copper foils on both sides to obtain a copper-free laminate 1, which was formed by laminating two prepregs 1.

Copper-Containing Laminate 2 (which was Prepared by Laminating One Prepreg 2)

The method for preparing the copper-containing laminate 2 is similar to that of the copper-containing laminate 1, and the difference is that the copper-containing laminate 2 is prepared by one prepreg 2.

### Copper-Free Laminate 2

The aforesaid copper-containing laminate 2 was etched to remove the copper foils on both sides to obtain a copper-free laminate 2, which was formed by laminating one prepreg 2.

Copper-Containing Laminate 3 (or Called as Copper-Clad Laminate 3, which was Prepared by Laminating Eight Prepregs 3)

Two hyper very low profile 3 (HVLP3) copper foils with a thickness of 18 μm and the same eight aforementioned prepregs 3 were provided. One copper foil, eight prepregs 3 and one copper foil were laminated in sequence, and the lamination was performed under a vacuum condition at 500 psi and 220° C. for 150 minutes to obtain a copper-containing laminate 3, which were prepared by eight identical prepregs 3.

### Copper-Free Laminate 3

The aforesaid copper-containing laminate 3 was etched to remove the copper foils on both sides to obtain a copper-free laminate 3, which was formed by laminating eight prepregs 3.

The test methods and characteristic analysis items for the aforementioned samples to be tested are explained as follows.

### Dissipation Factor (Df)

In the measurement of the dissipation factor, one copper-free laminate 1 in each Embodiments or Comparative embodiments was provided as a sample to be tested. A microwave dielectrometer (available from Japan AET company) was used. According to the method described in JIS C2565, each sample to be tested was measured at room temperature (about 25° C.) and at a frequency of 10 GHz. The lower the dissipation factor, the better the dielectric property of the sample to be tested. Under the measurement frequency of 10 GHz and the range where the dissipation factor Df value is less than 0.00150, the difference in the Df value less than 0.00003 represents no significant difference in the dissipation factor of different laminates, and the difference in the Df value greater than or equal to 0.00003 represents a significant difference in the dissipation factor of different laminates (there is significant technical difficulty). Under the measurement frequency of 10 GHz and the range where the dissipation factor Df value is greater than 0.00250 and less than 0.00600, the difference in the Df value less than 0.00050 represents no significant difference in the dissipation factor of different laminates, and the difference in the Df value greater than or equal to 0.00050 represents a significant difference in the dissipation factor of different laminates (there is significant technical difficulty).

### Copper Foil Peel Strength (Peel Strength, P/S)

One copper-containing laminate 3 in each Embodiments or Comparative embodiments was provided. The copper-containing laminate 3 (which was prepared by laminating eight prepregs 1) was cut into a rectangular sample with a width of 24 mm and a length greater than 60 mm, and the copper foil thereon was etched to leave a strip copper foil with a width of 3.18 mm and a length greater than 60 mm. According to the method described in IPC-TM-650 2.4.8, an universal tensile strength testing machine was used to measure the force required to pull the copper foil away from the surface of the laminate (unit: lbs/inch, lb/in) at room temperature (about 25° C.). The higher the copper foil peel strength, the better. The difference between the copper foil peel strength of different samples to be tested being greater than or equal to 0.20 lbs/inch represents a significant difference in the copper foil peel strength (there is significant technical difficulty). The difference between the copper foil peel strength of different samples to be tested being less than 0.20 lbs/inch represents no significant difference in the copper foil peel strength (there is no significant technical difficulty). The copper foil peel strengths of the copper-containing laminates 3 of Embodiments (E1 to E19) are all greater than 3.0 lbs/inch, for example, all greater than 3.2 lbs/inch, and for example, between 3.2 lbs/inch and 3.5 lbs/inch.

### T288 Heat Resistance

In the T288 heat resistance test, the above-mentioned copper-containing laminates 3 (formed by laminating eight prepregs 3, with a length and width of 6.5 mm×6.5 mm) in each Embodiments or Comparative embodiments were used as the samples to be tested. A thermal mechanical analyzer (TMA) was used to measure each sample to be tested at a constant temperature of 288° C. with reference to the method described in IPC-TM-650 2.4.24.1, and the board explosion time that the copper-containing laminates were exploded due to heat was recorded. The longer the board explosion time is, the higher the heat resistance of the copper-containing laminates produced using the resin composition is. If the test time exceeds 130 minutes without the board explosion, it will be marked as “>130”, which means that the sample to be test is not exploded after more than 130 minutes under the T288 heat resistance test. If the board explosion is occurred, the time that the sample is exploded is recorded (unit: minutes).

For example, the time that the products made using the resin compositions of the present invention are not exploded is greater than or equal to 130 minutes, for example, between 130 minutes to 140 minutes, and for example, between 130 minutes to 135 minutes.

### T320 Heat Resistance

In the T320 heat resistance test, the above-mentioned copper-containing laminates 3 (formed by laminating eight prepregs 3, with a length and width of 6.5 mm×6.5 mm) in each Embodiments or Comparative embodiments were used as the samples to be tested. A thermal mechanical analyzer (TMA) was used to measure each sample to be tested at a constant temperature of 320° C. with reference to the method described in IPC-TM-650 2.4.24.1, and the board explosion time that the copper-containing laminates were exploded due to heat was recorded. The longer the board explosion time is, the higher the heat resistance of the copper-containing laminates produced using the resin composition is. If the test time exceeds 60 minutes without the board explosion, it will be marked as “>60”, which means that the sample to be test is not exploded after more than 60 minutes under the T320 heat resistance test. If the board explosion is occurred, the time that the sample is exploded is recorded (unit: minutes).

For example, the time that the products made using the resin compositions of the present invention are not exploded is greater than or equal to 60 minutes, for example, between 60 minutes to 70 minutes, and for example, between 60 minutes to 65 minutes.

### Solder Dipping (S/D) Heat Resistance

The copper-containing laminate 3 (which was prepared by laminating eight prepregs 3) in each Embodiments or Comparative embodiments was used as the sample to be tested, which was cut into a sheet with a length of 20 cm and a width of 10 cm. Referring to the method described in IPC-TM-650 2.4.23, the sample to be tested was immersed in a tin furnace with a constant temperature of 288° C., and taken out after immersing for 20 seconds to check whether there is any explosion. If the board is exploded, it will fail and be marked “NG”. If the board is not exploded, it will pass the test and be marked “OK”. For example, interlayer delamination between insulating layers is called board explosion. The interlayer delamination will cause blistering and separation between any layers of the laminate.

### Heat Resistance Test on the Multilayer Laminate (Heat Resistance of Eight-Layer Laminate)

A core board was prepared according to the following method. One prepreg 3 prepared in each Embodiments and Comparative embodiments was respectively provided (the resin content of each prepreg 3 is about 58%). Hyper very low profile 3 (HVLP3) copper foils (with the thickness of 18 μm) were respectively laminated on both sides of the prepreg 3, and then pressed and cured under vacuum, high temperature (220° C.) and high pressure (500 psi) for 2.5 hours, and a copper-containing core board was obtained. Next, the copper foils on both sides of the above-mentioned copper-containing core board were etched to obtain a copper-free core board (with the thickness of 5 mils). Three copper-free core boards were prepared according to the aforesaid methods. Next, two hyper very low profile 3 (HVLP3) copper foils (with the thickness of 18 μm) and eight prepregs 4 which were prepared by impregnating 1080 L-glass fiber fabric with each sample to be tested (each of Embodiments or Comparative embodiments) (which was prepared using 1080 L-glass fiber fabric, wherein the resin content of each prepreg 4 is about 70%) were provided. One copper foil, two prepregs 4, one copper-free core board, two prepregs 4, one copper-free core board, two prepregs 4, one copper-free core board, two prepregs 4 and one copper foil were laminated in sequence, and the lamination was performed under a vacuum condition at 500 psi and 220° C. for 2.5 hours to obtain an eight-layer laminate with the outer layers being copper foils. The eight-layer laminate was cut into a rectangular sample with a length of 5.9 inches and a width of 2.2 inches. A total of 500 through holes with a diameter of 0.3 mm were formed on the surface of the rectangular sample using the circuit board drilling process (a 20×25 through hole array, wherein the vertical distance between adjacent hole walls is 0.25 mm). Electroplated copper was then formed on the hole walls to obtain a multilayer laminate sample for the heat resistance test.

In the heat resistance test of the multilayer laminate, the above multilayer laminate sample for the heat resistance test was used, and then the test was performed referring to the method described in IPC-TM-650 2.4.13.1. The sample was placed horizontally on (that is, contact) the tin liquid surface in a tin furnace with a constant temperature of 288° C. During each test, one side of the sample was placed on the tin surface for 10 seconds. After 10 seconds, the sample was removed from the tin surface and cooled at room temperature for 30 seconds. The same side of the sample was placed on the tin surface again for 10 seconds. After 10 seconds, the sample was taken out again and cooled at room temperature for 30 seconds. The sample is placed on the tin surface for 10 seconds and cooled at room temperature for 30 seconds, and the above steps are regarded as one time. The above steps were repeated to test the total number of times that each sample to be tested can withstand heat without board explosion. If the total number of tests exceeds 20 times and the board is still unexploded, it will be marked as “>20”. Generally, the greater the total number of times that each sample to be tested can be repeatedly subjected to the solder dipping heat resistance test without board explosion means that the heat resistance of the products (such as copper clad laminates) made by using the resin composition is better. The above-mentioned “board explosion” can be understood as interlayer peeling or blistering. Board explosion may occur between any layers of the laminate. For example, interlayer peeling between insulating layers can be called board explosion. For example, bubbling and separation between copper foil and insulating layers can also be called board explosion. Because the multilayer laminate contains multiple layers of copper foils and has been processed by the circuit board drilling process, the heat resistance test results thereof can truly reflect the heat resistance of the printed circuit board. The heat resistance test results of ordinary double-layer laminate without circuit board drilling process cannot accurately predict the heat resistance of multilayer laminates, that is, the heat resistance of printed circuit boards cannot be predicted. That is, the heat resistance test on the eight-layer laminate is one of the test methods to simulate the reliability of printed circuit boards.

### Percent of Thermal Expansion (PTE)

A copper-free laminate 3 (prepared by laminating eight prepregs) was selected as the sample to be tested for thermal mechanical analysis (TMA). The copper-free laminate 3 was cut into a sample with a width of 10 mm and a length of 10 mm. The sample was heated in the temperature range from 35° C. to 300° C. at a heating rate of 10° C. per minute. The percent of thermal expansion at Z-axis (unit: %) of each sample to be tested in the temperature range from 50° C. to 260° C. was measured according to the method described in IPC-TM-650 2.4.24.5. The lower the percent of thermal expansion, the better. The difference in the percent of thermal expansion rate greater than or equal to 0.1% is considered a significant difference, indicating a significant technical difficulty, and the difference in the percent of thermal expansion less than 0.1% is considered not significant. For example, the percent of expansion rate of the article made of the resin composition of the present invention measured by the method described in IPC-TM-650 2.4.24.5 is less than or equal to 2.0%, for example, between 1.7% and 2.0%.

### Moisture Absorption (by Pressure Cooking Test (PCT) Test)

The copper-free laminate 3 (prepared by laminating eight prepregs 3) was cut into a rectangular sample to be tested with a width of 2 inch and a length of 2 inch. Each sample to be tested was placed in an oven at 105±10° C. for 1 hour, then taken out and cooled at room temperature (about 25° C.) for 10 minutes, and the weight of the copper-free laminate 3 was weighed as W1. Then, referring to the method described in IPC-TM-650 2.6.16.1, a pressure cooking test (PCT) was performed for moisture absorption for 3 hours (test temperature 121° C. and relative humidity 100%), and then the remaining water on the surface of the laminate was removed. The weight of the copper-free laminate after moisture absorption and removing the remaining water is W2. According to the equation: moisture absorption W (%)=[(W2−W1)/W1]×100%, the moisture absorption by the PCT test can be calculated. The unit of the moisture absorption is %.

As far as this field is concerned, the lower the moisture absorption, the better. When the difference in moisture absorption of different samples is greater than or equal to 0.010%, it means that there is a significant difference in moisture absorption between different laminates, indicating that there is a significant technical difficulty. For example, the moisture absorption of an article made of a resin composition according to one embodiment of the present invention is less than or equal to 0.13%, for example, between 0.10% and 0.13%, and for example, between 0.108% and 0.127%.

Long Bubble Striation (Observing Whether there is Long Bubble Striation in Copper-Free Laminate)

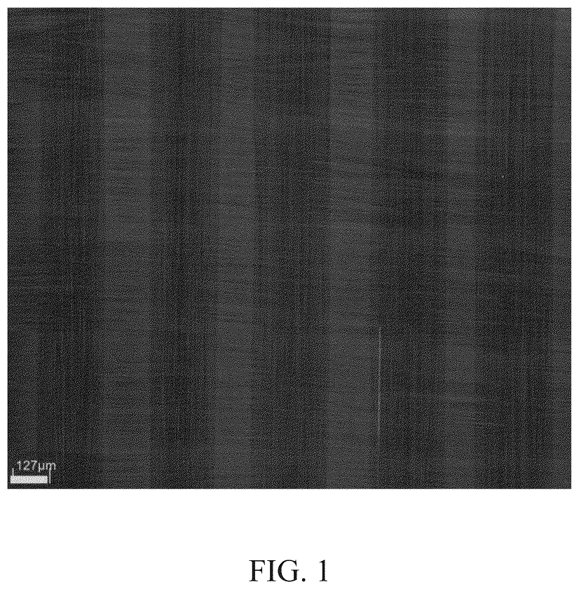

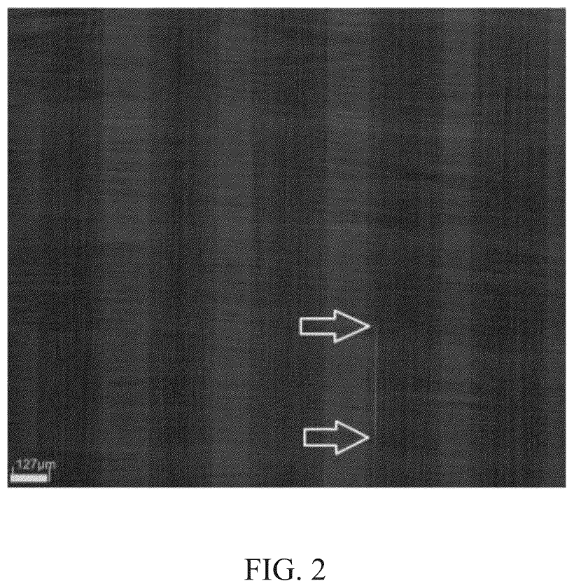

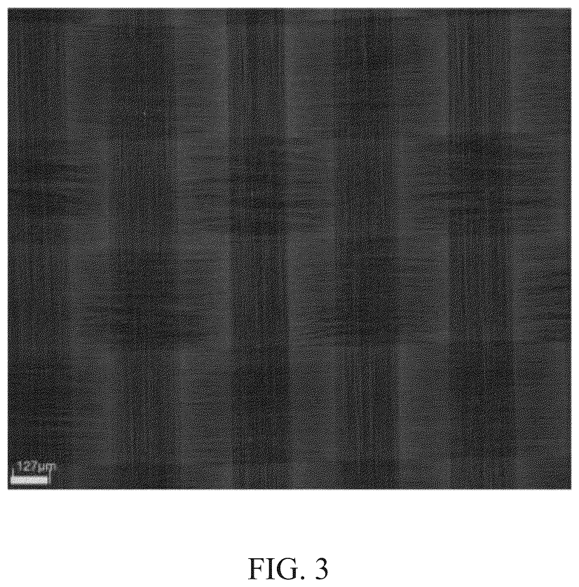

In the measurement of whether there is long bubble striation in the copper-free laminate, the copper-free laminate 2 (formed by lamination one prepreg 2) is selected as the sample to be tested and observed under an optical microscope. The testers used an optical microscope to observe whether there were long bubble striations inside the insulation layer of copper-free laminate X. If there is a long bubble striation with a length greater than or equal to 5 mils and less than or equal to 12 mils, it is judged as “yes”. If there is no long bubble striation with a length greater than or equal to 5 mils and less than or equal to 12 mils, it is judged as “no”. Similarly, if there is a long bubble striation with a length greater than or equal to 12 mils, it is judged as “yes”. If there is no long bubble striation with a length greater than or equal to 12 mils, it is judged as “no”. Please refer to FIG. 1 and FIG. 2. A striation with a length greater than or equal to 12 mils (5 mils equals to 127 microns; and 12 mils equals to 304.8 microns) is present in FIG. 1. The vertical long straight line indicated by the two arrows in FIG. 2 indicates that there is a long bubble striation with a length greater than or equal to 12 mils. FIG. 3 shows that there are no long bubble striations greater than or equal to 5 mils in length.

If there is long bubble striation on the insulation layer of the copper-containing laminate, the copper-free laminate or the printed circuit board, it will cause short circuit problem caused by conductive ion migration of conductive anodic filamentation (CAF) in the subsequent printed circuit board, causing the printed circuit board to fail and be scrapped.

According to the above embodiments, the articles made of the resin composition of the present invention, such as a prepreg, a resin film, a laminate or a printed circuit board, have excellent characteristics in at least one of the dissipation factor, reliability, percent of thermal expansion and moisture absorption, and thus can become a high-performance laminate that meets comprehensive requirements.

The above embodiments are essentially only auxiliary descriptions, and are not intended to limit the embodiments of the subject matter of the application or the applications or uses of these embodiments.

Although the present disclosure has been explained in relation to its embodiment, it is to be understood that many other possible modifications and variations can be made without departing from the spirit and scope of the disclosure as hereinafter claimed.

1. A resin composition, comprising:
70 parts by weight of a vinyl-containing resin;
3 parts by weight to 45 parts by weight of a polymer A; and
5 parts by weight to 55 parts by weight of a divinylbenzene-styrene-ethylene terpolymer,
wherein the vinyl-containing resin comprises a vinyl-containing polyphenylene ether resin, a maleimide resin, a vinyl-containing polyolefin or a combination thereof, and the polymer A comprises a compound represented by Formula (1), a compound represented by Formula (2), a compound represented by Formula (3), a compound represented by Formula (4), a compound represented by Formula (5), a compound represented by Formula (6) or a combination thereof, 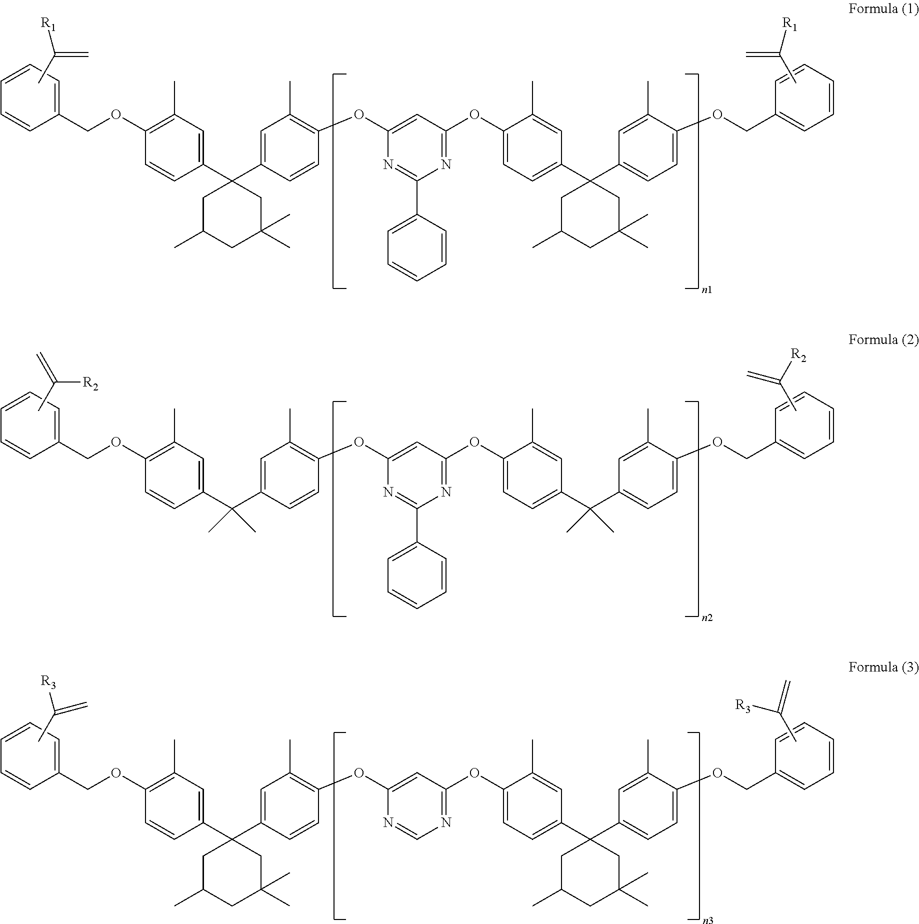 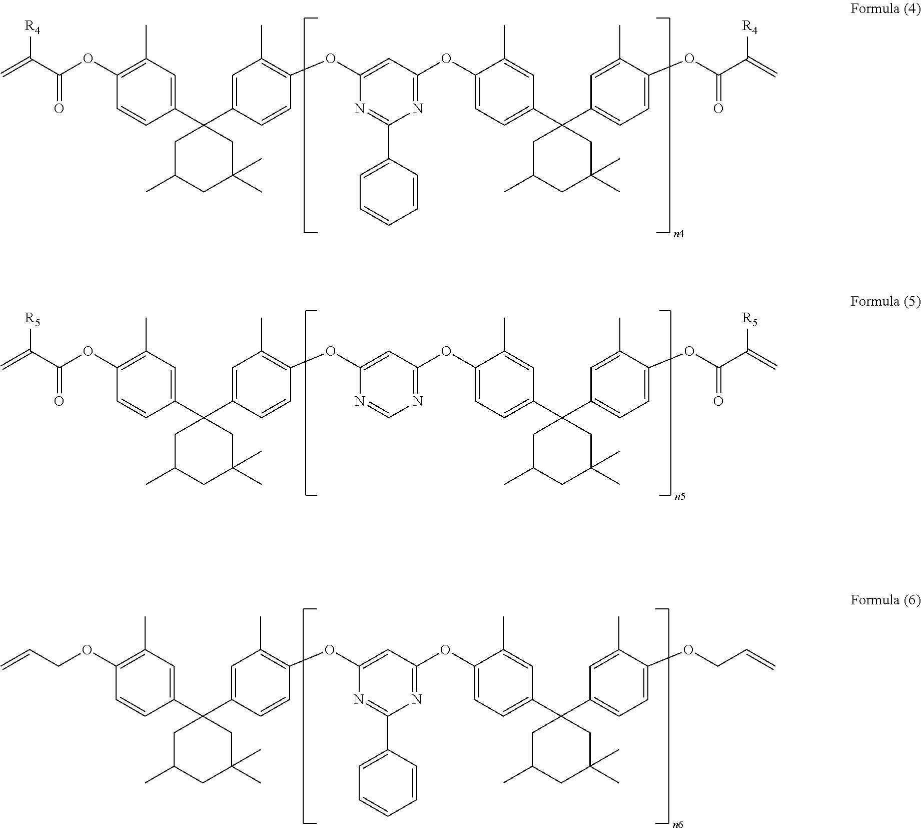
wherein each n1 to n6 independently is a weight average number of repeating units based on a weight average molecular weight, n1 is a value from 1 to 10, n2 is a value from 1 to 10, n3 is a value from 1 to 10, n4 is a value from 1 to 10, n5 is a value from 1 to 10, n6 is a value from 1 to 10, and each R₁ to R₅ independently is H or C₁ alkyl.

2. The resin composition of claim 1, wherein the compound represented by Formula (1) comprises a compound represented by Formula (1-1), a compound represented by Formula (1-2) or a combination thereof:

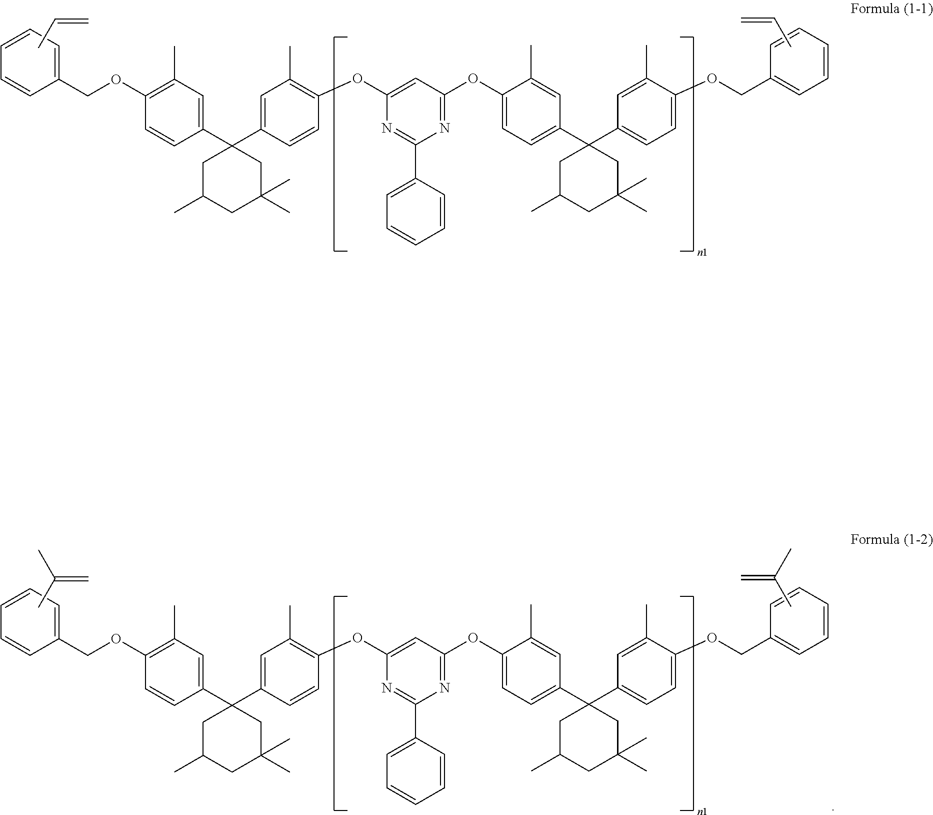

3. The resin composition of claim 2, wherein the compound represented by Formula (1-1) comprises a compound represented by Formula (1-1-1), a compound represented by Formula (1-1-2), a compound represented by Formula (1-1-3) or a combination thereof:

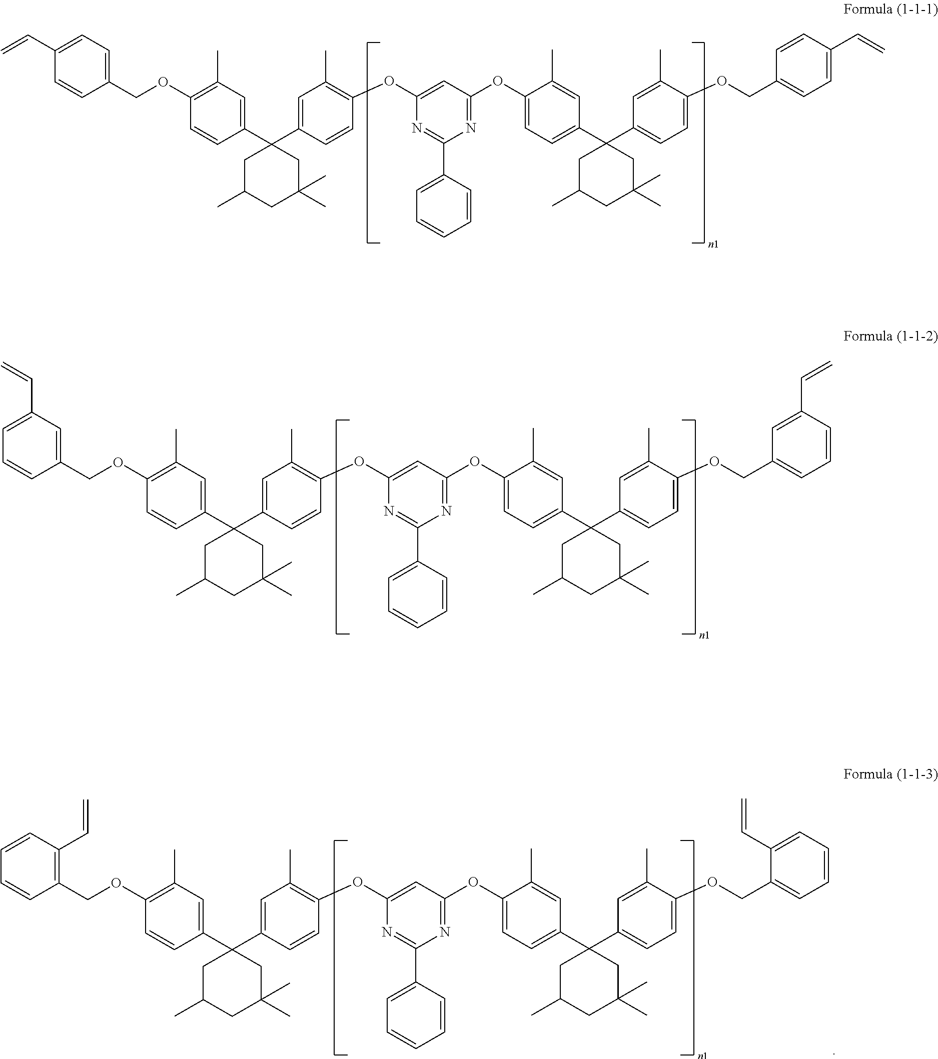

4. The resin composition of claim 2, wherein the compound represented by Formula (1-2) comprises a compound represented by Formula (1-2-1), a compound represented by Formula (1-2-2), a compound represented by Formula (1-2-3) or a combination thereof:

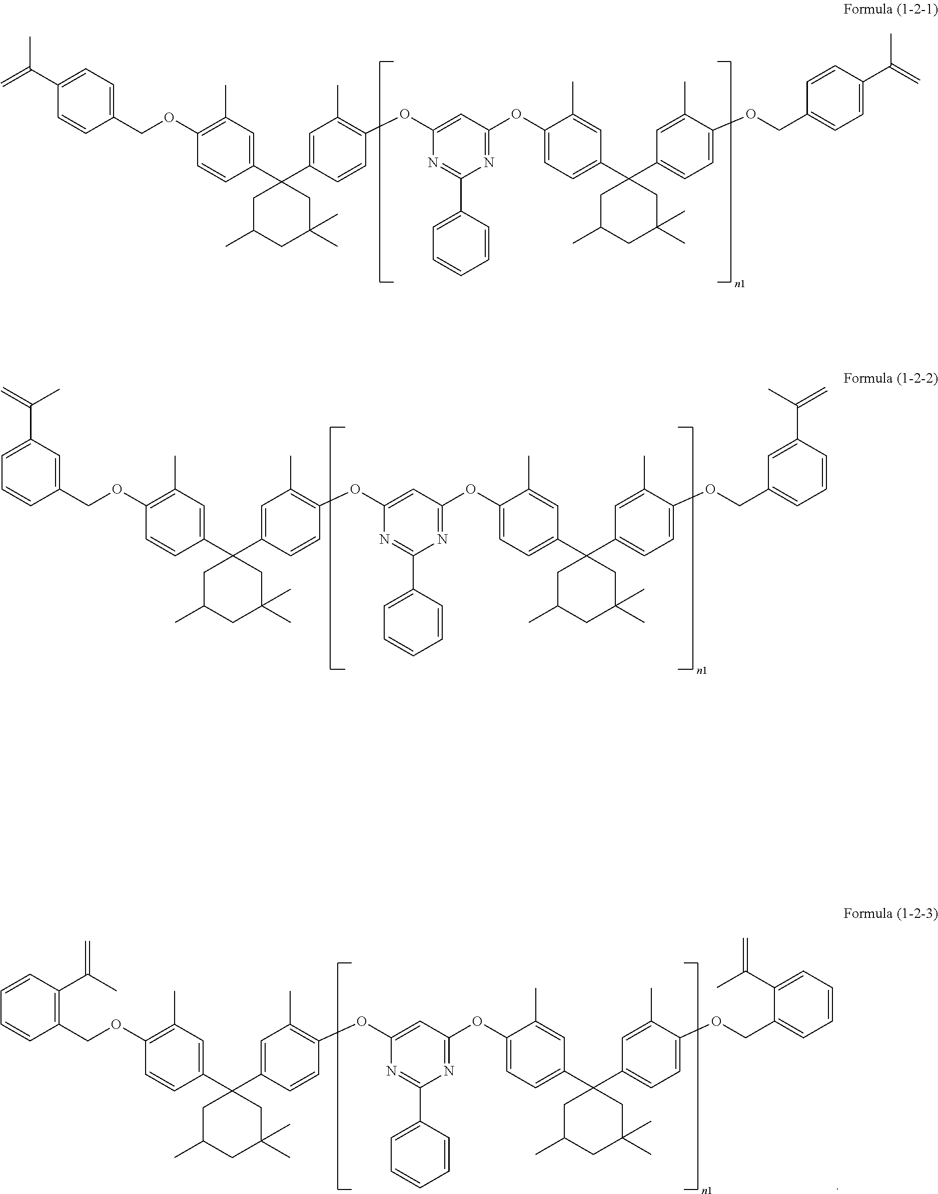

5. The resin composition of claim 1, wherein each the compound represented by Formula (1), the compound represented by Formula (2), the compound represented by Formula (3), the compound represented by Formula (4), the compound represented by Formula (5) and the compound represented by Formula (6) respectively has a weight average molecular weight ranging from 1,000 to 5,000.

6. The resin composition of claim 1, wherein the divinylbenzene-styrene-ethylene terpolymer has a number average molecular weight ranging from 5,000 to 15,000.

7. The resin composition of claim 1, wherein the divinylbenzene-styrene-ethylene terpolymer is formed by polymerization of a mixture, wherein the mixture comprises 40 mol % to 80 mol % of an ethylene monomer, 20 mol % to 60 mol % of a styrene monomer and 0.01 mol % to 10 mol % of a divinylbenzene monomer, and a total amount of the ethylene monomer, the styrene monomer and the divinylbenzene monomer is 100 mol %.

8. The resin composition of claim 1, wherein the vinyl-containing polyphenylene ether resin comprises vinylbenzyl-containing polyphenylene ether resin, (meth)acrylate-containing polyphenylene ether resin or a combination thereof.

9. The resin composition of claim 1, further comprising: hydrogenated polyolefin, wherein a content of the hydrogenated polyolefin is 0.1 parts by weight to 50 parts by weight.

10. The resin composition of claim 1, further comprising: acrylate, triallyl isocyanurate, triallyl cyanurate, styrene maleic anhydride copolymer resin, phenol resin, benzophenone resin, cyanate resin, polysiloxane resin, polyester resin, epoxy resin, polyamide resin, polyimide resin or a combination thereof.

11. The resin composition of claim 1, further comprising: an inorganic filler, an initiator, an inhibitor, a flame retardant, a colorant, a toughening agent, a core-shell rubber, a silane coupling agent, a solvent or a combination thereof.

12. An article manufactured using the resin composition of claim 1, wherein the article includes a prepreg, a resin film, a laminate or a printed circuit board.
